(19) United States
(12) Patent Application Publication
(10) Pub. No.: US 2003/0147299 A1
(43) Pub. Date: Aug. 7, 2003

(54) Semiconductor memory device capable of making switch between synchronizing signals for operation on data generated by different circuit configurations

(75) Inventor: Jun Setogawa, Hyogo (JP)

Correspondence Address: McDERMOTT, WILL & EMERY, 600 13th Street, N.W., Washington, DC, 20005-3096, US

(73) Assignee: Mitsubishi Denki Kabushiki Kaisha

(21) Appl. No.: 10/211,344

(22) Filed: Aug. 5, 2002

(30) Foreign Application Priority Data
Feb. 5, 2002 (JP) 2002-028336 (P)

(51) Int. Cl. G11C 8/00

(52) U.S. Cl. 365/233

(57) ABSTRACT

The semiconductor memory device includes a synchronizing signal generating circuit. The synchronizing signal generating circuit generates the internal clock, a dummy clock and the internal data strobe signal. The dummy clock is generated on the basis of clock by the same circuit configuration as the internal DQS generating circuit. Each of plural serial/parallel conversion circuits latch data sequentially in synchronism with the internal data strobe signal, the dummy clock and the internal clock to output the data to internal circuits. As a result, a switch can be performed between synchronizing signals for operation on data from the internal data strobe signal to the internal clock even if a circuit generating the internal data strobe signal is different from a circuit generating the internal clock.

### BACKGROUND OF THE INVENTION

1. Field of the Invention

The present invention relates to a semiconductor memory device inputting/outputting data to/from a memory cell in synchronism with a rise and a fall of a synchronizing signal.

2. Description of the Background Art

With progress in information industry in recent years, equipment supplying/receiving information has been sped up in operation and therefore, high speed operation has also been demanded in a semiconductor memory device storing data. In such circumstances, DDR-DRAM (Double Data Rate Dynamic Random Access Memory) to or from which data is inputted or outputted in synchronism with a rise and fall of a synchronizing signal has been put into practical use to cope with the high speed operation.

DDR-DRAM receives data from a controller of equipment in which DDR-DRAM is incorporated in synchronism with a data strobe signal DQS, latches the received data in synchronism with data strobe signal DQS and, thereafter, inputs/outputs the data to/from a memory cell in synchronism with a clock CLK.

Referring to FIG. 16, a conventional DDR-DRAM 300 includes: terminals 301 and 303, and 310 to 31n (n is an integer); input buffers 302 and 304; the internal CLK generating circuit 305; the internal DQS generating circuit 306; a power supply node 307; and serial/parallel conversion circuits 320 to 32n.

Terminal 301 supplies clock CLK received from outside to input buffer 302. Input buffer 302 buffers clock CLK from terminal 301 to output buffered clock CLK to internal CLK generating circuit 305.

Terminal 303 supplies data strobe signal DQS received from outside to input buffer 304. Input buffer 304 buffers data strobe signal DQS from terminal 303 to output buffered data strobe signal DQS to internal DQS generating circuit 306.

Internal CLK generating circuit 305 generates the internal clock int.CLK on the basis of clock CLK from input buffer 302 and an external power supply voltage ext.VDD from a power supply node 307 to supply generated internal clock int.CLK to serial/parallel conversion circuits 320 to 32n. Internal DQS generating circuit 306 generates the internal data strobe signal int.DQS on the basis of data strobe signal DQS from input buffer 304 and external power supply voltage ext.VDD from power supply node 307 to supply generated internal data strobe signal int.DQS to serial/parallel conversion circuits 320 to 32n.

Terminals 310 to 31n supply data DQ0 to DQn received from outside to respective serial/parallel conversion circuits 320 to 32n. Serial/parallel conversion circuits 320 to 32n convert data DQ0 to DQn received from terminals 310 to 31n from serial to parallel by means of a method described later to output the converted data to internal circuits including memory cells.

Referring to FIG. 17, each of serial/parallel conversion circuits 320 to 32n includes: a data input buffer 351; latch circuits 352 to 354, 363 to 367, and 369 to 374; N-channel MOS transistors 355, 357, 360 and 362; and P-channel MOS transistors 356, 358, 359 and 361; and an inverter 368.

Data input buffer 351 buffers input data DQ (one of DQ0 to DQn) inputted from one of terminals 310 to 31n to output buffered data DQ to latch circuits 352 and 354. Latch circuit 352 latches data DQ in synchronism with an inverted signal of internal data strobe signal int.DQS generated by internal DQS generating circuit 306 to output latched data DQ to latch circuit 353. Latch circuit 353 further latches data DQ latched by latch circuit 352, in synchronism with internal data strobe signal int.DQS to output data E0 to the source terminals of N-channel MOS transistor 355 and P-channel MOS transistor 356, and the source terminals of N-channel MOS transistor 357 and P-channel MOS transistor 358.

Latch circuit 354 latches data from data input buffer 351 in synchronism with internal data strobe signal int.DQS to output latched data O0 to the source terminals of P-channel MOS transistor 359 and N-channel MOS transistor 360, and the source terminals of P-channel MOS transistor 361 and N-channel MOS transistor 362.

N-channel MOS transistor 355 and P-channel MOS transistor 356 constitute a transfer gate and supplies data E0 to latch circuit 369 when being turned on by an address A3 from latch circuit 367 and address /A3 from inverter 368. N-channel MOS transistor 357 and P-channel MOS transistor 358 constitute a transfer gate and supplies data E0 to a node N4 when being turned on by address A3 from latch circuit 367 and address /A3 from inverter 368.

P-channel MOS transistor 359 and N-channel MOS transistor 360 constitute a transfer gate and supplies data O0 to a node N3 when being turned on by address A3 from latch circuit 367 and address /A3 from inverter 368. P-channel MOS transistor 361 and N-channel MOS transistor 362 constitute a transfer gate and supplies data O0 to a latch circuit 372 when being turned on by address A3 from latch circuit 367 and address /A3 from inverter 368. Latch circuit 363 latches address ADD in synchronism with an inverted signal of internal clock int.CLK supplied from internal CLK generating circuit 305 to output address ADD thus latched to latch circuit 364. Latch circuit 364 further latches the address latched by latch circuit 363, in synchronism with internal clock int.CLK to output the latched address to latch circuit 365. Latch circuit 365 further latches the address latched by latch circuit 364, in synchronism with an inverted signal of internal clock int.CLK to output the latched address to latch circuit 366. Latch circuit 366 further latches the address latched by latch circuit 365, in synchronism with internal clock int.CLK to output address A2 to latch circuit 367. Latch circuit 367 latches address A2 in synchronism with internal data strobe signal int.DQS from internal DQS generating circuit 306 to supply latched address A3 to the gate terminals of N-channel MOS transistors 355 and 362 and P-channel MOS transistors 358 and 359 and inverter 368. Inverter 368 inverts address A3 outputted from latch circuit 367 to supply inverted address /A3 to the gate terminals of P-channel MOS transistors 356 and 361 and N-channel MOS transistors 357 and 360.

Latch circuit 369 latches data E0 (or O0) supplied through node N3, in synchronism with an inverted signal of internal data strobe signal int.DQS to supply latched signal D0 to latch circuit 370. Latch circuit 370 latches data D0 in synchronism with an inverted signal of internal clock int.CLK to output latched data D2 to latch circuit 371. Latch circuit 371 latches data D2 in synchronism with internal clock int.CLK to supply latched data D3 to the internal circuit.

Latch circuit 372 latches data O0 (or E0) supplied through a node N4, in synchronism with an inverted signal of internal data strobe signal int.DQS to supply latched data D0 to latch circuit 373. Latch circuit 373 latches data D0 in synchronism with an inverted signal of internal clock int.CLK to output latched data D2 to latch circuit 374. Latch circuit 374 latches data D2 in synchronism with internal clock int.CLK to supply latched data D3 to the internal circuit.

Referring to FIG. 18, description will be given of operations that data is converted serial to parallel in each of serial/parallel conversion circuit 320 to 32n to make a switch between synchronizing signals for operation on the converted data from internal data strobe signal int.DQS to internal clock int.CLK.

When address ADD is supplied in synchronism with timing t20 of external clock ext.CLK, latch circuits 363 and 365, as described above, latches address ADD in synchronism with an inverted signal of internal clock int.CLK, latch circuits 364 and 366 latches address ADD in synchronism with internal clock int.CLK and latch circuit 366 outputs address A2 to latch circuit 367 in synchronism with timing t21.

Then, latch circuit 367 latches address A2 in synchronism with internal data strobe signal int.DQS to output address A3 in synchronism with timing t21 to the gate terminals of N-channel MOS transistors 355 and 362 and P-channel MOS transistors 358 and 359 and inverter 368. Inverter 368 inverts address A3 into address /A3 to output address /A3 to the gate terminals of P-channel MOS transistors 356 and 361 and N-channel MOS transistors 357 and 360.

On the other hand, data input buffer 351 buffers data DQ inputted in synchronism with external data strobe signal ext.DQS to output buffered data DQ to latch circuits 352 and 354. Latch circuit 352 latches data DQ in synchronism with an inverted signal of internal data strobe signal int.DQS and latch circuit 353 latches data latched by latch circuit 352, in synchronism with internal data strobe signal int.DQS to output latched data E0 in synchronism with timing t21 to the source terminals of N-channel MOS transistor 355 and P-channel MOS transistor 356, and the source terminals of N-channel MOS transistor 357 and P-channel MOS transistor 358. Latch circuit 354 latches data DQ in synchronism with internal data strobe signal int.DQS to output latched data O0 in synchronism with timing t21 to the source terminals of P-channel MOS transistor 359 and N-channel MOS transistor 360, and the source terminals of P-channel MOS transistor 361 and N-channel MOS transistor 362.

In this case, since external data strobe signal ext.DQS switches from L (logical low) level to H (logical high) level in synchronism with timing t21, latch circuit 352 not only capture data 1 prior to timing t21 and output it, but also maintains the output prior to timing t21 after timing t21 (internal data strobe signal int.DQS has the same phase as external data strobe signal ext.DQS). Since internal data strobe signal int.DQS stays at H level during a period between timings t21 to t22, latch circuit 353 outputs data 1 outputted from latch circuit 352. As a result, data E0 is constituted of data obtained by latching data 1 of data 1 and 2 inputted externally.

Since latch circuit 354 latches data DQ in synchronism with internal data strobe signal int.DQS, the circuit outputs data O0 in synchronism with timing t21. As a result, data O0 is constituted of part of data 1 inputted to latch circuit 354 at timing t21 or thereafter and data 2, of data 1 and 2 inputted externally.

Thereafter, latch circuits 369 and 372 latches data E0 or O0 in synchronism with an inverted signal of internal data strobe signal int.DQS to output latched data D0 to respective latch circuits 370 and 373 in synchronism with timing t22. In this case, since latch circuit 369 receives data E0 inputted through N-channel MOS transistor 355 and P-channel MOS transistor 356, or data O0 inputted through P-channel MOS transistor 359 and N-channel MOS transistor 360, the circuit outputs data D0 constituted of data 1 or 2. Since latch circuit 372 receives data E0 inputted through N-channel MOS transistor 357 and P-channel MOS transistor 358, or data O0 inputted through P-channel MOS transistor 361 and N-channel MOS transistor 362, the circuit outputs data D0 constituted of data 1 or 2.

Latch circuits 370 and 373 latch data D0 in synchronism with an inverted signal of internal clock int.CLK to output latched signal D2 to respective latch circuits 371 and 374 in synchronism with timing t22. Latch circuits 371 and 374 latch data D2 in synchronism with internal clock int.CLK to output latched signal D3 to the internal circuit in synchronism with timing t23.

In this way, each of serial/parallel conversion circuits 320 to 32n latches data DQ inputted in synchronism with external data strobe signal ext.DQS, in synchronism with internal data strobe signal int.DQS and thereafter, latches data in synchronism with internal clock int.CLK to give latched data to the internal circuit. That is, each of serial/parallel conversion circuits 320 to 32n captures data DQ into the internal circuit switching between synchronizing signals for operation on data from data strobe signal DQS to clock CLK.

In order to enable a smooth switch from data strobe signal DQS to clock CLK, tDSS is defined, as shown in FIG. 19, as a set-up time from a rising edge of clock CLK (means external clock ext.CLK) to a falling edge of data strobe signal DQS and tDSH is defined as a hold time of data strobe signal DQS from a rising edge of clock CLK. Set-up time tDSS and hold time tDSH are used in control to prevent an unfavorable operation in which data strobe signal DQS shifts in phase relative to clock CLK and thereby, a time from a rising edge of clock CLK to a falling edge of data strobe signal DQS is shorter than set-up time tDSS or hold time tDSH, and usually set so as to be tDSS=tDSH=0.2 tCLK.

While in FIG. 18, there is shown a case where no phase difference exists between external data strobe signal ext.DQS and internal data strobe signal int.DQS and no phase difference exists between external clock ext.CLK and internal clock int.CLK, in actuality internal data strobe signal int.DQS lags behind external data strobe signal ext.DQS in phase. Moreover, internal clock int.CLK lags behind external clock ext.CLK in phase.

Then, referring to FIG. 20, description will be given of operation in serial/parallel conversion circuits 320 to 32n in a case where internal data strobe signal int.DQS lags behind external data strobe signal ext.DQS in phase and internal clock int.CLK lags behind external clock ext.CLK in phase. Note that FIG. 20 shows a case where hold time tDASH=0.5 tCLK, that is, external clock ext.CLK coincides with external data strobe signal ext.DQS in phase.

Each of serial/parallel conversion circuits 320 to 32n receives data ext.DQS in synchronism with timing t24 of external data strobe signal ext.DQS. Internal DQS generating circuit 306 generates internal data strobe signal int.DQS later than external data strove signal ext.DQS in phase by a delay amount DT7 on the basis of external data strobe signal ext.DQS. Internal CLK generating circuit 305 generates internal clock signal int.CLK later than external clock ext.CLK in phase by a delay amount DT8 on the basis of external clock ext.CLK. Data input buffer 351 buffers data ext.DQ to supply the buffered data as data int.DQ to latch circuits 352 and 354.

Then, latch circuits 352 to 354 latch data int.DQ in synchronism with timing t25 in the same operation as that described above, latch circuits 369 and 372 output data D0 in synchronism with timing t26, latch circuits 370 and 373 output data D2 in synchronism with timing t27 and latch circuits 371 and 374 output data D3 in synchronism with timing t28. In the case where external data strobe signal ext.DQS coincides with external clock ext.CLK in phase in such a way, a smooth switch is performed between synchronizing signals for operation on data from internal data strobe signal int.DQS to internal clock int.CLK.

In a case where external data strobe signal ext.DQS shifts from external clock ext.CLK in phase, that is when hold time tDSH assumes the minimum value tDSHmin as shown in FIG. 21, a problem arises that a switch cannot be performed between synchronizing signals for operation on data from internal data strobe signal int.DQS to internal clock int.CLK.

Referring to FIG. 21, latch circuits 352 and 354 receive data int.DQ from data input buffer 351 in synchronism with timing t25 to latch received data int.DQ. Latch circuits 369 and 372 output data D0 in synchronism with timing t26. Then, latch circuits 370 and 373 latches data D0 in synchronism with an inverted signal of internal clock int.CLK to output latched data D2 in synchronism with timing t26. In this case, since latch circuits 370 and 373 output data D2 to latch circuits 371 and 374 only during a period from timing t26 to before timing t30, latch circuits 371 and 374 have no inputted data therein when being activated at timing t30 and cannot output data constituted of latched data D2 to internal circuits.

As a result, when external data strobe signal ext.DQS shifts from external clock ext.CLK in phase such that hold time tDASH assumes the minimum value tDASHmin, a problem arises that a switch cannot be performed between synchronizing signals for operation on data from internal data strobe signal int.DQS to internal clock int.CLK. This problem becomes especially conspicuous in a case where DDR-DRAM is operated at higher speed, which is caused by a difference in voltage dependency or temperature dependency between a circuit generating the internal data strobe signal int.DQS and a circuit generating the internal clock int.CLK.

### SUMMARY OF THE INVENTION

It is, therefore, an object of the present invention to provide a semiconductor memory device capable of making a switch between synchronizing signals for operation on data from the internal data strobe signal int.DQS to the internal clock int.CLK even in a case where a circuit generating the internal data strobe signal int.DQS and a circuit generating the internal clock int.CLK are different from each other.

According to the present invention, a semiconductor memory device inputting/outputting data to/from memory cells data in synchronism with a rise and a fall of a synchronizing signal, includes: a plurality of memory cells; a synchronizing signal generating circuit receiving first and second synchronizing signals, generating a first internal synchronizing signal on the basis of the first synchronizing signal, generating a second internal synchronizing signal on the basis of the second synchronizing signal, and generating a third internal synchronizing signal by means of the same circuit configuration as a circuit generating one of the first and second internal synchronizing signals on the basis of one of the first and second synchronizing signal; a peripheral circuit inputting/outputting data to/from each of the plurality of memory cells in synchronism with the rise and the fall of the second internal synchronizing signal; and an input circuit receiving data inputted externally in synchronism with the first synchronizing signal, latching the received data sequentially in synchronism with the first internal synchronizing signal, the third internal synchronizing signal and the second internal synchronizing signal to output the latched data to the peripheral circuit.

Data is inputted to the semiconductor memory device in synchronism with the first synchronizing signal. The first internal synchronizing signal is generated on the basis of the first synchronizing signal, and the second internal synchronizing signal is generated on the basis of the second synchronizing signal. The third internal synchronizing signal is generated by the same circuit configuration as the circuit generating one of either first and second internal synchronizing signals on the basis of one of either first and second synchronizing signals. Data inputted to the semiconductor memory device is sequentially latched by the first internal synchronizing signal, the third internal synchronizing signal and the second synchronizing signal, and written to memory cells in synchronism with the second internal synchronizing signal.

Therefore, according to the present invention, a smooth switch can be made between synchronizing signals for operation on data from the first internal synchronizing signal to the second internal synchronizing signal even in a case where the circuit generating the first internal synchronizing signal and the circuit generating the second internal synchronizing are different from each other.

The foregoing and other objects, features, aspects, and advantages of the present invention will become more apparent from the following detailed description of the present invention when taken in conjunction with the accompanying drawings.

### BRIEF DESCRIPTION OF THE DRAWINGS

FIG. 1 is a schematic block diagram of a semiconductor memory device according to a first embodiment;

FIG. 2 is a block diagram for describing a synchronizing signal generating circuit and an input circuit shown in FIG. 1;

FIG. 3 is a circuit diagram of the internal CLK generating circuit shown in FIG. 2;

FIG. 4 is a circuit diagram of a dummy CLK generating circuit shown in FIG. 2;

FIG. 5 is a circuit diagram of an internal DQS generating circuit shown in FIG. 2;

FIG. 6 is a circuit diagram of a serial/parallel conversion circuit shown in FIG. 2;

FIG. 7 is a circuit diagram of a latch circuit latching data in synchronism with a clock;

FIG. 8 is a circuit diagram of a latch circuit latching data in synchronism with an inverted clock;

FIG. 9 is a timing chart for describing operation in the first embodiment of the serial/parallel conversion circuit shown in FIG. 6;

FIG. 10 is another timing chart for describing operation in the first embodiment of the serial/parallel conversion circuit shown in FIG. 6;

FIG. 11 is a schematic block diagram of a semiconductor memory device according to a second embodiment;

FIG. 12 is a block diagram for describing a synchronizing signal generating circuit and an input circuit shown in FIG. 11;

FIG. 13 is a circuit diagram of a dummy DQS generating circuit shown in FIG. 12;

FIG. 14 is a timing chart for describing operation in the second embodiment of the serial/parallel conversion circuit shown in FIG. 6;

FIG. 15 is another timing chart for describing operation in the second embodiment of the serial/parallel conversion circuit shown in FIG. 6;

FIG. 16 is a block diagram of part of a prior art semiconductor memory device;

FIG. 17 is a circuit diagram of a serial/parallel conversion circuit shown in FIG. 16;

FIG. 18 is a timing chart for describing operation in the serial/parallel conversion circuit shown in shown in FIG. 17;

FIG. 19 is a timing chart of a data strobe signal and an external clock for describing a set-up time and a hold time;

FIG. 20 is another timing chart for describing operation in the serial/parallel conversion circuit shown in shown in FIG. 17; and

FIG. 21 is still another timing chart for describing operation in the serial/parallel conversion circuit shown in shown in FIG. 17.

### DESCRIPTION OF THE PREFERRED EMBODIMENTS

Detailed description will be given of embodiments of the present invention with reference to the accompanying drawings. Note that the same symbols are attached to the same or corresponding constituents in the figures and none of descriptions thereof is repeated.

First Embodiment

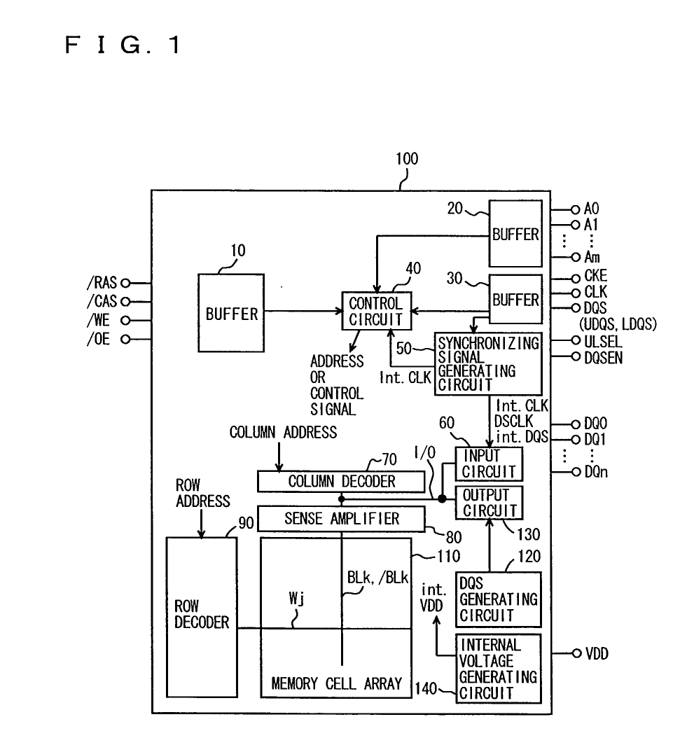

Referring to FIG. 1, a semiconductor memory device 100 according to the first embodiment of the present invention includes: buffers 10, 20 and 30; a control circuit 40; a synchronizing signal generating circuit 50; an input circuit 60; a column decoder 70; a sense amplifier 80; a low decoder 90; a memory cell array 110; a DQS generating circuit 120; an output circuit 130; and an internal voltage generating circuit 140.

Buffer 10 receives a row address strobe signal /RAS, a column address strobe signal /CAS; a write enable signal /WE and an output enable signal /OE, buffers control signals such as row address strobe signal /RAS to output buffered control signals such as buffered row address strobe signal /RAS to control circuit 40.

Buffer 20 receives address A0 to Am (m is an integer) to buffer received address A0 to Am. Buffer 20 outputs buffered address A0 to Am to control circuit 40 and input circuit 60. Note that in FIG. 1, a signal line from buffer 20 to input circuit 60 is omitted for easy understanding of the figure.

Buffer 30 receives a clock enable signal CKE, a clock CLK, a data strobe signal DQS (UDQS or LDQS), a data strobe enable signal DQSEN, and a select signal ULSEL; not only outputs received signals: clock enable signal CKE, clock CLK, data strobe signal DQS, data strobe enable signal DQSEN, and select signal ULSEL to synchronizing signal generating circuit 50, but also outputs received clock enable signal CKE to control circuit 40.

Control circuit 40 determines validity of internal clock int.CLK according to whether or not clock enable signal CKE received from buffer 30 at a rising edge of internal clock int.CLK received from synchronizing signal generating circuit 50 is at H level. Control circuit 40, when determining that internal clock int.CLK is valid, performs various kinds of controls on the basis of control signals such as row address strobe signal /RAS inputted from buffer 10.

That is, control circuit 40 outputs address A0 to Am inputted from buffer 20 at a timing at which row address strobe signal /RAS is switched from H level to L level, as a row address in synchronism with internal clock int.CLK to row decoder 90. Furthermore, control circuit 40 outputs address A0 to Am inputted from buffer 20 at a timing at which column address strobe signal /CAS is switched from H level to L level, as a column address in synchronism with internal clock int.CLK to column decoder 70. Moreover, control circuit 40 outputs write enable signal /WE in synchronism with internal clock int.CLK to input circuit 60 and outputs output enable signal /OE in synchronism with internal clock int.CLK to output circuit 130.

Synchronizing signal generating circuit 50 generates internal clock int.CLK on the basis of clock CLK to output generated internal clock int.CLK to control circuit 40 and input circuit 60. Furthermore, synchronizing signal generating circuit 50, as described later, generates internal data strobe signal int.DQS on the basis of data strobe signal DQS, data strobe enable signal DQSEN and select signal ULSEL to output generated internal data strobe signal int.DQS to input circuit 60. Moreover, synchronizing signal generating circuit 50 generates a dummy clock DSCLK according to a method described later on the basis of clock CLK and data strobe signal DQS to output generated dummy clock DSCLK to input circuit 60.

Input circuit 60 receives data DQ0 to DQn inputted in synchronism with data strobe signal DQS, receives address A0 to Am from buffer 20 and receives internal data strobe signal int.DQS, internal clock int.CLK and dummy clock DSCLK from synchronizing signal generating circuit 50. Furthermore, input circuit 60 not only latches data DQ0 to DQn in synchronism with internal data strobe signal int.DQS, but also converts data DQ0 to DQn from serial to parallel on the basis of address A0 to Am and thereafter, latches data converted to parallel sequentially in synchronism with dummy clock DSCLK and internal clock int.CLK. That is, input circuit 60 converts data DQ0 to DQn from serial to parallel to output converted data to input/output line I/O making a switch between synchronizing signals for operation on data from internal data strobe signal int.DQS to internal clock int.CLK through dummy clock DSCLK. Description will be given of detailed operation in input circuit 60 later.

Column decoder 70 decodes a column address from control circuit 40 to activate a bit line pair BLk and /BLk (k is a natural number) designated by the decoded column address. Sense amplifier 80, in data writing, receives write data from input circuit 60 through input/output lines I/O to write received write data onto activated bit line pair BLk and /BLk. Moreover, sense amplifier 80, in data reading, amplifies read data read out from activated bit line pair BLk and /BLk to output the read data to output circuit 130 through input/output lines I/O.

Row decoder 90 decodes a row address inputted from control circuit 40 to activate a word line Wj (j is a natural number) designated by the decoded row address. While it is a word line driver that activates word line j, row decoder 90, in FIG. 1, decodes a row address and activates word line Wj.

Memory cell array 110 includes: plural memory cells arranged in a (j×k) matrix; plural bit line pairs BLk and /BLk; plural word lines Wj; and plural equalize circuits provided correspondingly to respective plural bit line pairs BLk and /BLk.

DQS generating circuit 120, when data is outputted from semiconductor memory device 100 to outside, generates data strobe signal DQS to output generated data strobe signal DQS to output circuit 130. Output circuit 130 outputs read data from sense amplifier 80 to the external terminal in synchronism with data strobe signal DQS from DQS generating circuit 120. Internal voltage generating circuit 140 generates an internal power supply voltage int.VDD on the basis of an external power supply voltage VDD to output generated internal power supply voltage int.VDD to synchronizing signal generating circuit 50. Note that while other internal power supply voltages used in semiconductor memory device 100 includes: a precharge voltage used in equalization of bit line pair BLk and /BLk; a cell plate voltage supplied to a cell plate electrode of a memory cell and others, the internal power supply voltages have no direct relation with the contents of the present invention, so in FIG. 1, there is shown only internal power supply voltage int.VDD, which has a relation with the contents of the present invention.

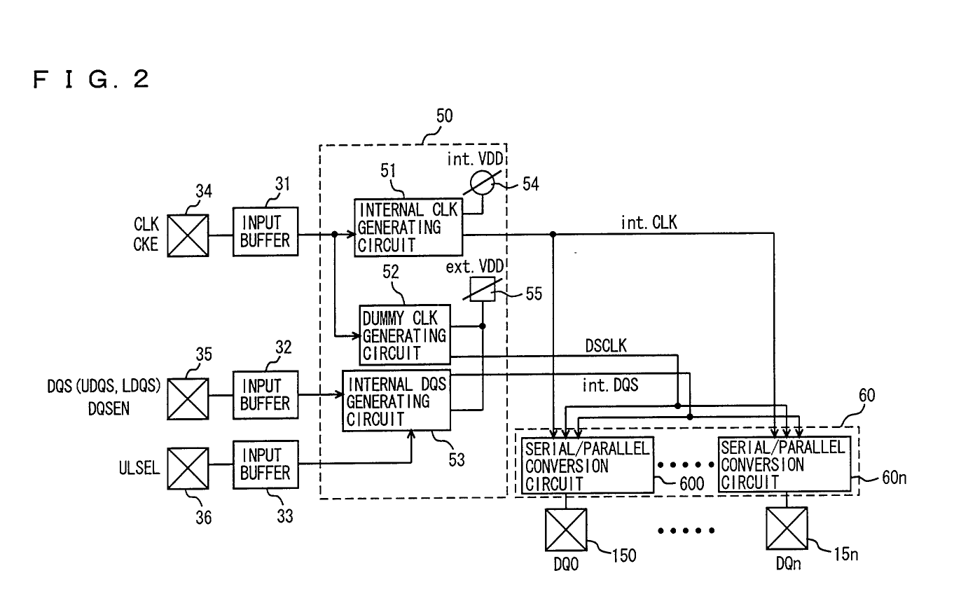

Referring to FIG. 2, synchronizing signal generating circuit 50 includes: an internal CLK generating circuit 51; a dummy CLK generating circuit 52; and an internal DQS generating circuit 53. Input circuit 60 includes: serial/parallel conversion circuits 600 to 60n corresponding to respective terminals 150 to 15n. In FIG. 2, buffer 30 shown in FIG. 1 is shown as input buffers 31 to 33 in correspondence to terminal 34 inputted with clock CLK and clock enable signal CLE, terminal 35 inputted with data strobe signal DQS and data strobe enable signal DQSEN, and terminal 36 inputted with select signal ULSEL.

Internal CLK generating circuit 51 generates internal clock int.CLK on the basis of clock CLK (that is, external clock ext.CLK) and clock enable signal CKE received through terminal 34 and input buffer 31, and internal power supply voltage int.VDD from a power supply node 54 according to a method described later to output generated internal clock int.CLK to input circuit 60.

Dummy CLK generating circuit 52 has the same circuit configuration as internal DQS generating circuit 53. Dummy CLK generating circuit 52 generates dummy clock DSCLK on the basis of clock CLK (that is, external clock ext.CLK) from input buffer 31 and external power supply voltage ext.VDD from a power supply node 55 according to a method described later to output generated dummy clock DSCLK to input circuit 60.

Internal DQS generating circuit 53 generates internal data strobe signal int.DQS on the basis of data strobe signal DQS (that is, external data strobe signal ext.DQS) from input buffer 32, data strobe enable signal DQSEN from input buffer 32, select signal ULSEL from input buffer 33 and external power supply voltage ext.VDD from power supply node 55 according to a method described later to output generated internal data strobe signal int.DQS to input circuit 60.

Note that semiconductor memory device 100, when inputting/outputting data of 16 bits, does not receive data of 16 bits in synchronism with one data strobe signal DQS, but divides data of 16 bits into data pieces of 8 bits to receive data of first 8 bits in synchronism with data strobe signal UDQS and to receive data of the residual 8 bits in synchronism with LDQS. Therefore, in this case, two data strobe signals UDQS and LDQS are inputted to semiconductor memory device 100.

Internal DQS generating circuit 53 generates internal data strobe signal int.DQS on the basis of data strobe signals UDQS and LDQS as described later.

Each of serial/parallel conversion circuits 600 to 60n receives internal clock int.CLK from internal CLK generating circuit 51, dummy clock DSCLK from dummy CLK generating circuit 52 and internal data strobe signal int.DQS from internal DQS generating circuit 53, not only converts input data DQ0 to DQn inputted from corresponding terminals 150 to 15n, from serial to parallel, in synchronism with internal data strobe signal int.DQS, but also latches converted data sequentially in synchronism with internal data strobe signal int.DQS, dummy clock DSCLK, and internal clock int.CLK. Each of serial/parallel conversion circuits 600 to 60n outputs latched data to input/output lines I/O.

Description will be given of detailed operation in serial/parallel conversion circuits 600 to 60n.

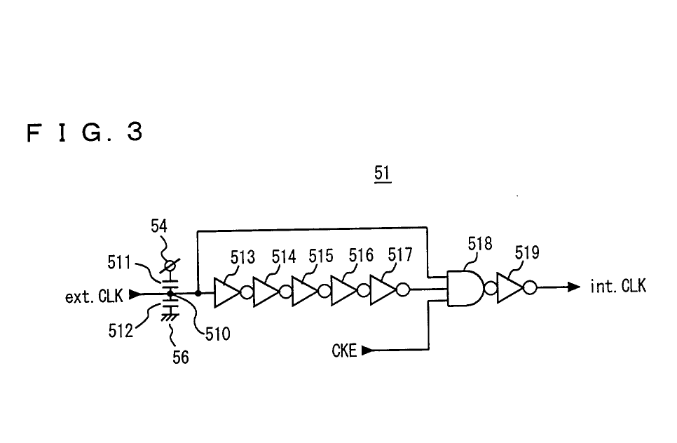

Referring to FIG. 3, internal CLK generating circuit 51 includes: power supply node 54; a ground node 56; capacitors 511 and 512; inverters 513 to 517 and 519; and a NAND gate 518.

Capacitor 511 is connected between a node 510 and power supply node 54 and capacitor 512 is connected between node 510 and ground node 56. Capacitor 511 renders a falling slope in pulse of external clock ext.CLK from H level down to L level gentler and capacitor 512 renders a rising slope in pulse of external clock ext.CLK from L level up to H level gentler.

Each of inverters 513 to 517 inverts an input signal to output an output signal. Inverters 513 to 517 delays external clock ext.CLK by a prescribed time whose rising and falling slopes in pulse are rendered gentler by capacitors 511 and 512 to output the delayed signal to NAND gate 518. NAND gate 518 performs a logical product operation on external clock ext.CLK whose rising and falling slopes in pulse are rendered gentler by capacitors 511 and 512, external clock ext.CLK delayed by a prescribed time and clock enable signal CKE and inverts a result of the operation to output the inverted result to inverter 519. Inverter 519 inverts an output signal of NAND gate 518 to output internal clock int.CLK.

Since NAND gate 518, when clock enable signal CKE is at H level, performs a logical product operation on two external clocks ext.CLK having a phase difference therebetween by a total delay amount of inverters 513 to 517, a signal having a period at H level corresponding to the total delay amount of inverters 513 to 517 is generated by the logical product operation. Since internal clock int.CLK is a signal obtained by 2 time inversions of the signal generated by a logical product operation on two external clocks ext.CLK in NAND gate 518, internal clock int.CLK stays at H level during a period corresponding to the total delay amount of inverters 513 to 517. Note that since clock enable signal CKE has a relation in phase with external clock ext.CLK that clock enable signal CKE is at H level when external clock ext.CLK rises from L level to H level, NAND gate 518 performs the above logical product operation.

Therefore, internal CLK generating circuit 51 delays external clock ext.CLK by a prescribed amount with inverters 513 to 517 and the delay amount determines a period during which internal clock int.CLK stays at H level, that is a duty. The reason why a duty of internal clock int.CLK to be generated is determined in internal CLK generating circuit 51 is that since external clock ext.CLK with a determined duty is not inputted to semiconductor memory device 100, the correct determination is effected, in semiconductor memory device 100, on a duty of internal clock int.CLK for use in inputting/outputting of data to/from a memory cell.

Note that while in the above description, the number of stages of inverters delaying a phase of external clock ext.CLK by a prescribed amount is set to 5, an odd number of stages for inverters generally is only required in the present invention. In that case, the number of stages of inverters is determined according to a duty of a desired internal clock int.CKL to be generated.

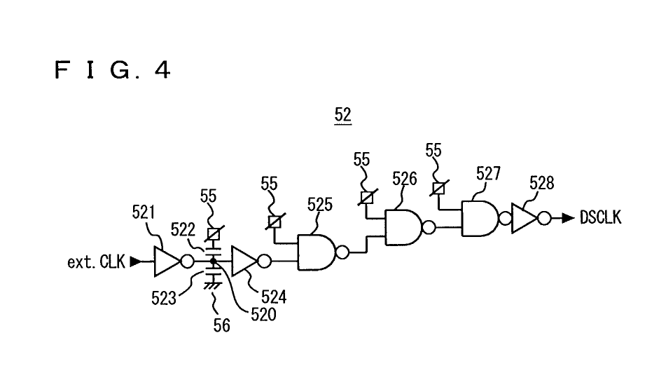

Referring to FIG. 4, dummy CLK generating circuit 52 includes: inverters 521, 524 and 528; capacitors 522 and 523; and NAND gates 525 to 527.

Capacitor 522 is connected between a node 520 and power supply node 55 and capacitor 523 is connected between node 520 and ground node 56. Capacitors 522 and 523 exercise the same function as capacitors 511 and 522 in internal CLK generating circuit 51.

Inverter 521 inverts external clock ext.CLK from input buffer 31 to output the inverted clock to node 520. Inverter 524 inverts a signal, which is outputted from inverter 521 and whose rising and falling slopes are rendered gentler by capacitors 522 and 523, to output the inverted signal to the other terminal of NAND gate 525. NAND gate 525 receives a signal at H level of external power supply voltage ext.VDD supplied to power supply node 55 at one terminal thereof and receives an output signal of inverter 524 at the other terminal. NAND gate 525 performs a logical product operation on received two signals to invert a result of the operation and to output the inverted result to the other terminal of NAND gate 526.

NAND gate 526 receives a signal at H level of external power supply voltage ext.VDD supplied to power supply node 55 at one terminal thereof and an output signal of NAND gate 525 at the other terminal thereof. NAND gate 526 performs a logical product operation on received two signals to invert a result of the operation and to output the inverted result to the other terminal of inverter 527.

NAND gate 527 receives a signal at H level of external power supply voltage ext.VDD supplied to power supply node 55 at one terminal thereof and an output signal of NAND gate 526 at the other terminal thereof. NAND gate 527 performs a logical product operation on received two signals to invert a result of the operation and to output the inverted result to the other terminal of inverter 528. Inverter 528 inverts the output of NAND gate 527 to output dummy clock DSCLK.

Since NAND gates 525 to 527 each receive a signal at H level of external power supply voltage ext.VDD at one terminal thereof, each outputs an output signal obtained by inverting a logical level of an input signal. Therefore, NAND gates 525 to 527 each exercise almost the same function as that of inverters 521, 524 and 528. As a result, dummy CLK generating circuit 52 is constructed of: inverters 521, 524 and 528 at 3 stages; and NAND gates 525 to 527 at 3 stages. The inversion elements at 6 stages are connected in series with each other.

Note that the reason why external power supply voltage ext.VDD is supplied to one terminals of NAND gates 525 to 527 is that by using the same external power supply voltage as external power supply voltage ext.VDD supplied to internal DQS generating circuit 53, a voltage dependency of dummy CLK generating circuit 52 is made to be the same as a voltage dependency of internal DQS generating circuit 53.

Inversion elements constituting dummy CLK generating circuit 52 are not limited to inversion elements at 6 stages, but have only to be inversion elements at an even number of stages. In that case, dummy CLK generating circuit 52 is constructed of an odd number of inversion elements (inverters) and an odd number of inversion elements (NAND gates).

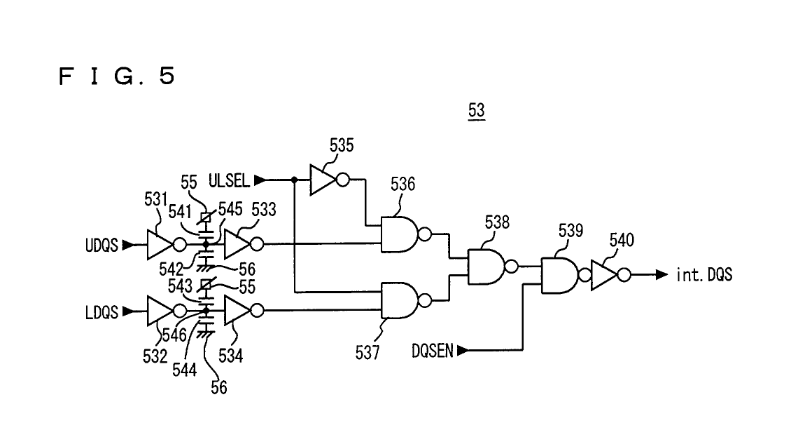

Referring to FIG. 5, internal DQS generating circuit 53 includes: inverters 531 to 534, 535 and 540; NAND gates 536 to 539; and capacitors 541 to 544. Capacitor 541 is connected between power supply node 55 and a node 545, capacitor 542 is connected between node 545 and ground node 56. Capacitor 543 is connected between power supply node 55 and a node 546 and capacitor 544 is connected between node 546 and ground node 56. Capacitors 541, 542; 543 and 544 exercise the same function as capacitors 511 and 512 of internal CLK generating circuit 51.

Inverter 531 receives data strobe signal UDQS from input buffer 32 to invert data strobe signal UDQS and to output the inverted signal to node 545. Inverter 532 receives data strobe signal LDQS from input buffer 32 to invert data strobe signal LDQS and to output the inverted signal to node 546.

Inverter 533 inverts data strobe signal UDQS, which is outputted from inverter 531 and whose rising and falling slopes are rendered gentler by capacitors 541 and 542, to output the inverted signal to the other terminal of NAND gate 536. Inverter 534 inverts data strobe signal LDQS, which is outputted from inverter 532 and whose rising and falling slopes are rendered gentler by capacitors 543 and 544, to output the inverted signal to the other terminal of NAND gate 537.

Inverter 535 inverts select signal ULSEL from input buffer 33 to output the inverted signal to one terminal of NAND gate 536. NAND gate 536 performs a logical product operation on an output signal of inverter 535 and an output signal of inverter 533 to invert a result of the operation and to output the inverted result to one terminal of NAND gate 538. NAND gate 537 performs a logical product operation on select signal ULSEL from input buffer 33 and an output signal of inverter 534 to inverts a result of the operation and to output the inverted result to the other terminal of NAND gate 538.

NAND gate 538 performs a logical product operation on an output signal of NAND gate 536 and an output signal of NAND gate 537 to invert a result of the operation and to output the inverted result to one terminal of NAND gate 539. NAND gate 539 performs a logical product operation on data strobe enable signal DQSEN from input buffer 32 and an output signal of NAND gate 538 to invert a result of the operation and to output the inverted result to inverter 540. Inverter 540 inverts an output signal of NAND gate 539 to output internal data strobe signal int.DQS.

Select signal ULSEL is a signal for selecting data strobe signal UDQS or LDQS as data strobe signal DQS. Select signal ULSEL is at L level when data is inputted to semiconductor memory device 100 in synchronism with data strobe signal UDQS, while being at H level when data is inputted to semiconductor memory device 100 in synchronism with data strobe signal LDQS.

Data strobe enable signal DQSEN is a signal for activating/deactivating internal DQS generating circuit 53 and internal DQS generating circuit 53 is deactivated when data strobe enable signal DQSEN is at L level, while being activated when data strobe enable signal DQSEN is at H level.

Internal DQS generating circuit 53 is activated in response to data strobe enable signal DQSEN at H level and NAND gate 537, when receiving select signal ULSEL at L level, outputs a signal at H level regardless of a logical level of an output signal from inverter 534. Since NAND gate 536 receives a signal at H level from inverter 535 at one terminal thereof, the gate outputs an output signal from inverter 533, that is a signal in response to a logical level of data strobe signal UDQS, to one terminal of NAND gate 538. Furthermore, since NAND gate 538 receives a signal at H level from inverter 537, the gate outputs an output signal in response to a logical level of an output signal of NAND gate 536 to one terminal of NAND gate 539. Moreover, since NAND gate 539 receives data strobe enable signal DQSEN at H level at the other terminal thereof, the gate outputs a signal in response to a logical level of an output signal of NAND gate 538 to inverter 540.

Therefore, internal DQS generating circuit 53, when select signal ULSEL is at L level, generates internal data strobe signal int.DQS on the basis of data strobe signal UDQS with inverter 531, capacitors 541 and 542, inverter 533, NAND gates 536, 538 and 539, and inverter 540. In this case, inverter 531, capacitors 541 and 542, inverter 533, NAND gates 536, 538 and 539, and inverter 540 correspond to inverter 521, capacitors 522 and 523, inverter 524, NAND gates 525, 526 and 527 and inverter 528, respectively, of dummy CLK generating circuit 52 (see FIG. 4).

On the other hand, when select signal ULSEL at H level is inputted to internal DQS generating circuit 53, inverter 535 outputs a signal at L level to one terminal of NAND gate 536. Then, NAND gate 536 outputs a signal at H level regardless of a logical level of an output signal from inverter 533. Since NAND gate 537 receives select signal ULSEL at H level at one terminal thereof, the gate outputs a signal in response to a logical level of an output signal from inverter 534, that is a signal in response to a logical level of data strobe signal LDQS, to NAND gate 538.

Since NAND gate 538 receives a signal at H level from NAND gate 536 at one terminal thereof, the gates outputs a signal in response to a logical level of an output signal from NAND gate 537 to at one terminal of NAND gate 539. Operations thereafter are as described above.

Accordingly, when select signal ULSEL is at H level, internal DQS generating circuit 53 generates internal data strobe signal int.DQS on the basis of data strobe signal LDQS with inverter 532, capacitors 543 and 544, inverter 534, NAND gates 537, 538 and 539 and inverter 540. In this case, inverter 532, capacitors 543 and 544, inverter 534, NAND gates 537, 538 and 539 and inverter 540 correspond to inverter 521, capacitors 522 and 523, inverter 524 and NAND gates 525, 526 and 527 and inverter 528, respectively, of dummy CLK generating circuit 52 (see FIG. 4).

Internal DQS generating circuit 53, in such a fashion, selects data strobe signal UDQS or LDQS with select signal ULSEL to generate internal data strobe signal int.DQS on the basis of selected data strobe signal UDQS (or LDQS). As described above, a circuit configuration in internal DQS generating circuit 53 generating internal data strobe signal int.DQS on the basis of data strobe signal UDQS; and a circuit configuration in internal DQS generating circuit 53 generating internal data strobe signal int.DQS on the basis of data strobe signal LDQS are the same as that of dummy CLK generating circuit 52.

That is, dummy CLK generating circuit 52 generates dummy clock DSCLK based on external clock ext.CLK with the same circuit configuration as that in internal DQS generating circuit 53, by which a voltage dependency or a temperature dependency as a circuit characteristic is made the same as that of internal DQS generating circuit 53, and enables a switch between synchronizing signals for operation on data from dummy clock DSLK to internal clock int.CLK.

Accordingly, the first embodiment has a feature that dummy CLK generating circuit 52 generates dummy clock DSCLK on the basis of external clock ext.CLK with the same circuit configuration as that in internal DQS generating circuit 53.

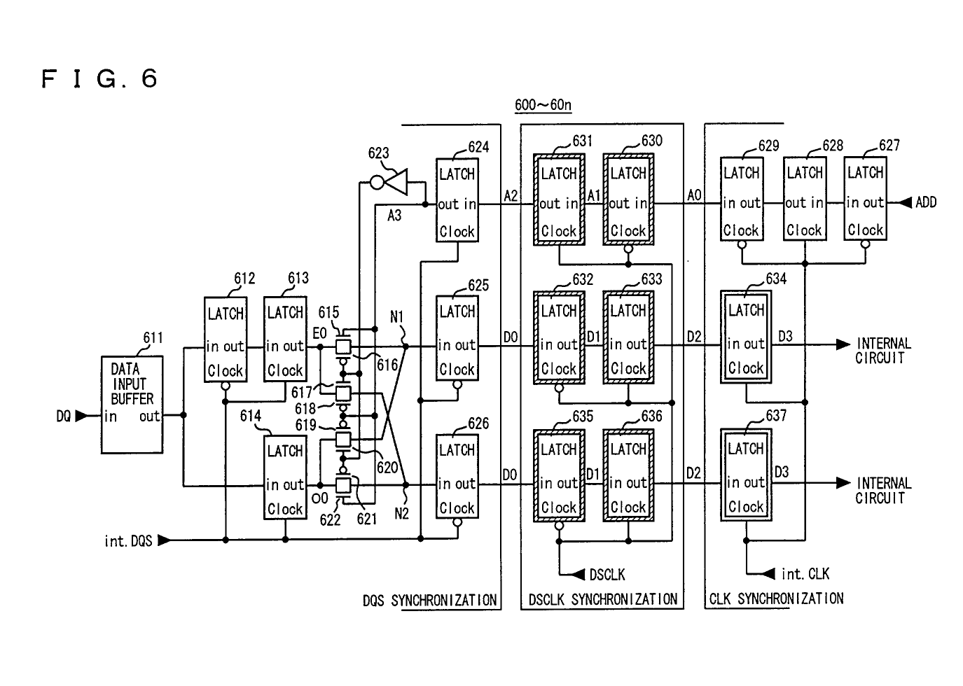

Referring to FIG. 6, each of serial/parallel conversion circuits 600 to 60n includes: a data input buffer 611; latch circuits 612 to 614 and 624 to 637; N-channel MOS transistors 615, 617, 620 and 622; and P-channel MOS transistors 616, 618, 619 and 621.

Data input buffer 611 receives data DQ (one of data DQ0 to DQn) from a corresponding terminal (one of terminals 150 to 15n) to each of serial/parallel conversion circuits 600 to 60n to buffer received data DQ. Data input buffer 611 outputs buffered data to latch circuits 612 and 614.

Latch circuit 612 latches data DQ in synchronism with an inverted signal of internal data strobe signal int.DQS from internal DQS generating circuit 53 to output latched data to latch circuit 613. Latch circuit 613 latches data latched by latch circuit 612, in synchronism with internal data strobe signal int.DQS to output latched data E0 to the source terminals of N-channel MOS transistor 615 and P-channel MOS transistor 616 and the source terminals of N-channel MOS transistor 617 and P-channel MOS transistor 618.

Latch circuit 614 latches data DQ from data input buffer 611 in synchronism with internal data strobe signal int.DQS to output latched data O0 to the source terminals of P-channel MOS transistor 619 and N-channel MOS transistor 620 and the source terminals of P-channel MOS transistor 621 and N-channel MOS transistor 622.

N-channel MOS transistor 615 and P-channel MOS transistor 616 constitute a transfer gate. N-channel MOS transistor 615 receives address A3 from latch circuit 624 at the gate terminal thereof and P-channel MOS transistor 616 receives address /A3 from inverter 623 at the gate terminal thereof N-channel MOS transistor 615 and P-channel MOS transistor 616, when being turned on by addresses A3 and /A3, outputs data E0 to latch circuit 625.

N-channel MOS transistor 617 and P-channel MOS transistor 618 constitute a transfer gate. N-channel MOS transistor 617 receives address /A3 from inverter 623 at the gate terminal thereof and P-channel MOS transistor 618 receives address A3 from latch circuit 624 at the gate terminal thereof. N-channel MOS transistor 617 and P-channel MOS transistor 618, when being turned on by addresses A3 and /A3, outputs data E0 to latch circuit 626 through node N2.

P-channel MOS transistor 619 and N-channel MOS transistor 620 constitute a transfer gate. P-channel MOS transistor 619 receives address A3 from latch circuit 624 at the gate terminal thereof and N-channel MOS transistor 620 receives address /A3 from inverter 623 at the gate terminal thereof. P-channel MOS transistor 619 and N-channel MOS transistor 620, when being turned on by addresses A3 and /A3, outputs data O0 to latch circuit 625 through node N1.

P-channel MOS transistor 621 and N-channel MOS transistor 622 constitute a transfer gate. P-channel MOS transistor 621 receives address /A3 from inverter 623 at the gate terminal thereof and N-channel MOS transistor 622 receives address A3 from latch circuit 624 at the gate terminal thereof. P-channel MOS transistor 621 and N-channel MOS transistor 622, when being turned on by addresses A3 and /A3, outputs data O0 to latch circuit 626.

Latch circuit 627 latches address ADD (means A0 to Am) inputted from buffer 20 in synchronism with an inverted signal of internal clock int.CLK from internal CLK generating circuit 51 to output latched address to latch circuit 628. Latch circuit 628 latches address latched by latch circuit 627, in synchronism with internal clock int.CLK to output latched address to latch circuit 629. Latch circuit 629 latches address latched by latch circuit 628, in synchronism with an inverted signal of internal clock int.CLK to output latched address A0 to latch circuit 630.

Latch circuit 630 latches address A0 in synchronism with a inverted signal of dummy clock DSCLK from dummy CLK generating circuit 52 to output latched address A1 to latch circuit 631. Latch circuit 631 latches address A1 in synchronism with dummy clock DSCLK to output latched address A2 to latch circuit 624. Latch circuit 624 latches address A2 in synchronism with internal data strobe signal int.DQS to output latched address A3 to the gate terminals of N-channel MOS transistors 615 and 622 and P-channel MOS transistors 618 and 619 and inverter 623. Inverter 623 inverts address A3 to output inverted address /A3 to the gate terminals of P-channel MOS transistors 616 and 621 and N-channel MOS transistors 617 and 620.

Latch circuit 625 latches data E0 (or O0) that the circuit receives through node N1, in synchronism with an inverted signal of internal data strobe signal int.DQS to output latched data D0 to latch circuit 632. Latch circuit 626 latches data O0 (or EO) that the circuit receives through node N2, in synchronism with an inverted signal of internal data strobe signal int.DQS to output latched data D0 to latch circuit 635.

Latch circuits 632 and 635 latches data D0 in synchronism with an inverted signal of dummy clock DSCLK to output latched data D1 to respective latch circuits 633 and 636. Latch circuits 633 and 636 latch data D1 in synchronism with dummy clock DSCLK to output latched data D2 to respective latch circuits 634 and 637. Latch circuits 634 and 637 latch data D2 in synchronism with internal clock int.CLK to output latched data D3.

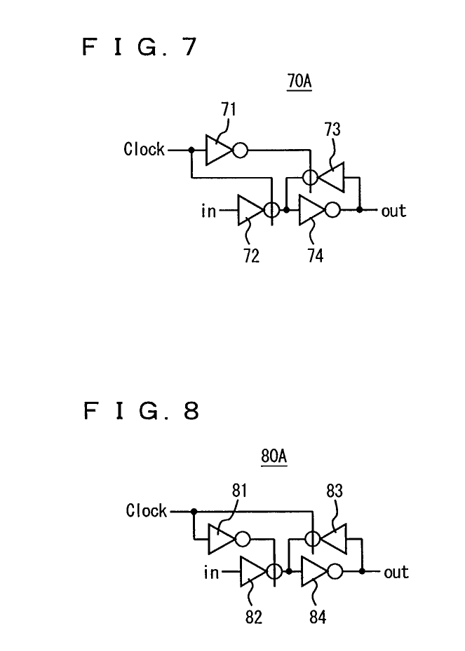

A circuit configuration of each of latch circuits 613, 614, 624, 628, 631, 633, 634, 636 and 637 latching an input signal in synchronism with a synchronizing signal such as internal data strobe signal int.DQS, dummy clock DSCLK, internal clock int.CLK or the like is shown as a latch circuit 70A in FIG. 7. Referring to FIG. 7, latch circuit 70A is constructed of inverters 71 to 74. Inverter 71 inverts clock Clock to output the inverted clock to inverter 73. Inverter 72 inverts an input signal to output the inverted signal to inverter 74 when clock Clock that the inverter receives is at H level. Inverter 72 does not output an output signal when clock Clock that the inverter receives is at L level.

Inverter 74 inverts signals from inverters 72 and 73 to output an output. Inverter 73 inverts a signal from inverter 74 to output the inverted signal to inverter 74 when a signal from inverter 71 is at H level while not outputting an output signal when a signal from inverter 71 is at L level.

Latch circuit 70A outputs an input signal as is during a period when clock signal Clock is at H level. Latch circuit 70A maintains a signal having been outputted during a period when clock Clock is at H level when clock Clock switches from H level to L level. That is, a signal is latched by inverters 73 and 74.

A configuration of each of latch circuits 612, 625, 626, 627, 629, 630, 632 and 635 latching an input signal in synchronism with an inverted signal of a synchronizing signal such as internal data strobe signal int.DQS, dummy clock DSCLK and internal clock int.CLK or the like is shown as a latch circuit 80A in FIG. 8. Referring to FIG. 8, latch circuit 80A is constructed of inverters 81 to 84. Inverter 81 inverts clock Clock to output the inverted clock to inverter 82. Inverter 82 inverts an input signal to output the inverted signal to inverter 84 when a signal from inverter 81 is at H level. Inverter 82 does not output an output signal when a signal from inverter 81 is at L level.

Inverter 84 inverts a signal from inverters 82 and 83 to output an output signal. Inverter 83 inverts a signal from inverter 84 to output the inverted signal to inverter 84 when clock Clock is at H level, while not outputting an output signal when clock Clock is at L level.

Latch circuit 80A outputs an input signal as is during period when clock Clock is at L level. Latch circuit 80A maintains a signal having been outputted during a period when clock Clock is at L level when clock Clock switches from L level to H level. That is, in this case, a signal is latched by inverters 83 and 84.

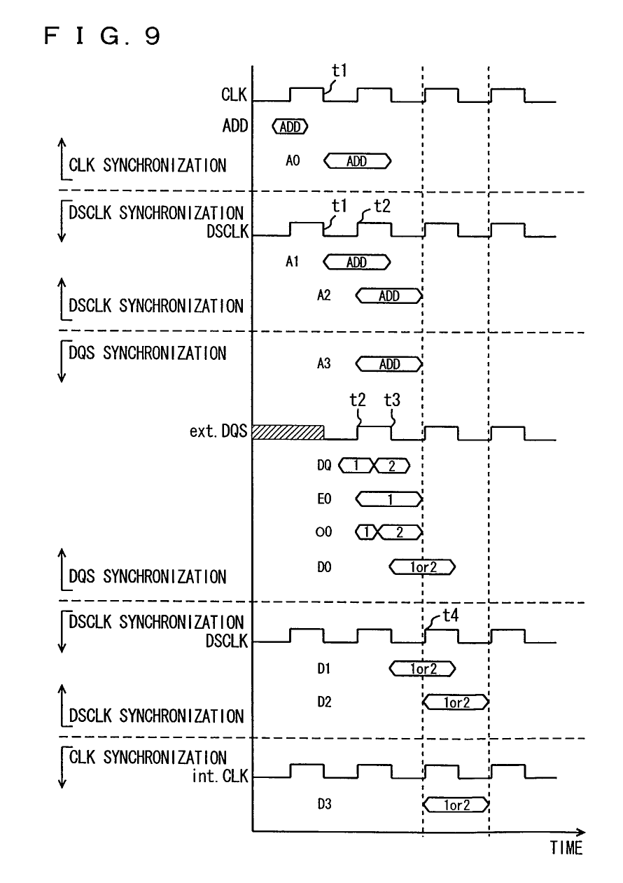

Referring to FIGS. 6 and 9, description will be given of operation in each of serial/parallel conversion circuits 600 to 60n. Latch circuit 627, when receiving address ADD from buffer 20, latches address ADD in synchronism with the inverted signal of internal clock signal int.CLK to output latched address to latch circuit 628. Latch circuit 628 latches address latched by latch circuit 627, in synchronism with internal clock int.CLK and latch circuit 629 latches address latched by latch circuit 628, in synchronism with the inverted signal of internal clock int.CLK to output latched address A0 to latch circuit 630 in synchronism with timing t1.

Latch circuit 630 latches address A0 in synchronism with the inverted signal of dummy clock DSCLK from dummy CLK generating circuit 52. In this case, since timing t1 at which address A0 is outputted from latch circuit 629 is a timing at which dummy clock DSCLK falls from H level to L level, latch circuit 630 outputs address A0 received from larch circuit 629 at timing t1 to output latch circuit 631 as address A1. Latch circuit 631 latches address A1 in synchronism with dummy clock DSCLK to output latched address A2 in synchronism with timing t2 at which dummy clock DSCLK switches from L level to H level to latch circuit 624.

Then, latch circuit 624 latches address A2 in synchronism with internal data strobe signal int.DQS to output latched address A3 to the gate terminals of N-channel MOS transistors 615 and 622 and P-channel MOS transistors 618 and 619 and inverter 623. In this case, since internal data strobe signal int.DQS (indicated by [ext.DQS] in FIG. 9) switches from L level to H level at timing t2 at which latch circuit outputs 631 outputs address A2, latch circuit 624 is activated at timing t2 to output address A2 as address A3 in synchronism with timing t2.

On the other hand, data input buffer 611 receives data DQ (one of data DQ0 to DQn) from a corresponding terminal (one of terminals 150 to 15n) in synchronism with external data strobe signal ext.DQS to buffer received data DQ. Data input buffer 611 outputs buffered data DQ to latch circuits 612 and 614. Then, since latch circuit 612 receives data DQ at a timing prior to timing t2, the circuit outputs received data DQ to latch circuit 613 during a period from a timing at which the circuit receives data DQ for the first time till timing t2. While latch circuit 612 receives internal data strobe signal int.DQS whose logical level has switched from L level to H level at timing t2 to be deactivated, the circuit maintains the previous outputting state prior to the deactivation, so the circuit continues to output data DQ to latch circuit 613. Then, since latch circuit 613 is activated at timing t2, the circuit outputs data received from latch circuit 612 as data E0, in synchronism with timing t2 to the source terminals of N-channel MOS transistor 615 and P-channel MOS transistor 616 and the source terminals of N-channel MOS transistor 617 and P-channel MOS transistor 618. In this case, data E0 is constituted only of data 1 of data 1 and 2 constituting data DQ.

On the other hand, latch circuit 614 has been deactivated at a timing at which latch circuit 614 receives data DQ for the first time from data input buffer 611 in order to latch data DQ in synchronism with internal data strobe signal int.DQS and does not output data. Latch circuit 614, after being activated at timing t2, outputs data DQ as data O0 to the source terminals of P-channel MOS transistor 619 and N-channel MOS transistor 620 and the source terminals of P-channel MOS transistor 621 and N-channel MOS transistor 622. In this case, since latch circuit 614, when being activated at timing t2, outputs data DQ as is, data O0 is constituted of part of data 1 and part of data 2 inputted to latch circuit 614 at timing t2 and thereafter.

Since the transfer gate constituted of N-channel MOS transistor 615 and P-channel MOS transistor 616 and the transfer gate constituted of N-channel MOS transistor 617 and P-channel MOS transistor 618 are complementarily turned on/off by addresses A3 and /A3, data E0 is given to latch circuit 625 or latch circuit 626. Since the transfer gate constituted of P-channel MOS transistor 619 and N-channel MOS transistor 620 and the transfer gate constituted of P-channel MOS transistor 621 and N-channel MOS transistor 622 are complementarily turned on/off by addresses A3 and /A3, data O0 is given to latch circuit 625 or latch circuit 626. Therefore, latch circuits 625 and 626 outputs data D0 constituted of data 1 or data 2 to respective latch circuits 632 and 635. In this case, since latch circuits 625 and 626 latches data E0 (or O0) in synchronism with the inverted signal of internal data strobe signal int.DQS, the circuits are inactive at timing t2 at which the circuits receive data E0 (or O0) for the first time and are activated at timing t3 followed by outputting data D0 in synchronism with timing t3.

Since latch circuits 632 and 635 latch data in synchronism with the inverted signal of dummy clock DSCLK, the circuits are active at timing t3 at which the circuits receive data D0 for the first time to output data D0 received from latch circuits 625 and 626 in a state as it has been received, as data D1, to respective latch circuits 633 and 636. Since latch circuits 633 and 636 latch data in synchronism with dummy clock DSCLK, the circuits are inactive at timing t3 at which the circuits receive data D1 for the first time, latch data D1 by timing t4 at which the circuits are activated and output latched data D2 to respective latch circuits 634 and 637 in synchronism with timing t4. Then, since latch circuits 634 and 637 latch data in synchronism with internal clock int.CLK, the circuits are active at timing t4 at which the circuits receive data D2 for the first time to output data D2 received from latch circuits 633 and 636, as data D3 in synchronism with timing t4.

In such a fashion, each of serial/parallel conversion circuits 600 to 60n not only converts data DQ from serial to parallel in synchronism with internal data strobe signal int.DQS, but also latches data DQ sequentially in synchronism with internal data strobe signal int.DQS, dummy clock DSCLK and internal clock int.CLK and thereby performs a switch between synchronizing signals for operation on data DQ inputted in synchronism with external data strobe signal ext.DQS from internal data strobe signal int.DQS to internal clock int.CLK for use in inputting/outputting of data to/from a memory cell.

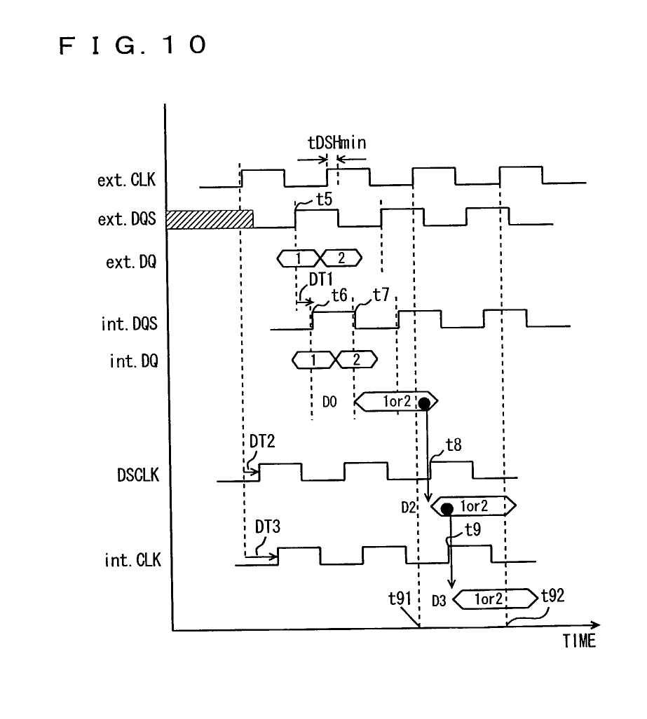

FIG. 9 shows a case where external data strobe signal ext.DQS coincides with external clock ext.CLK in phase, internal data strobe signal int.DQS does not lag behind external data strobe signal ext.DQS, and internal clock int.CLK and dummy clock DSCLK do not lag behind external clock ext.CLK. In actuality, however, external data strobe signal ext.DQS does not coincide with external clock ext.CLK in phase, internal data strobe signal int.DQS lags behind external data strobe signal ext.DQS, and internal clock int.CLK and dummy clock DSCLK lag behind external clock ext.CLK. FIG. 10 shows a case where a phase difference arises between external data strobe signal ext.DQS and external clock ext.CLK and a phase delay occurs in each of internal data strobe signal int.DQS, dummy clock DSCLK and internal clock int.CLK. In FIG. 10, hold time tDSH indicating a phase difference between external data strobe signal ext.DQS and external clock ext.CLK is the minimum value tDSHmin and a delay amount of internal data strobe signal int.DQS relative to external data strobe signal ext.DQS is DT1, a delay amount of dummy clock DSCLK relative to external clock ext.CLK is DT2 and a delay amount of internal clock int.CLK relative to external clock ext.CLK is DT3.

Referring to FIG. 10, the operation from the time when address ADD is inputted to latch circuit 627 from buffer 20 till the time when latch circuit 624 outputs address A3 is as described above.

On the other hand, data input buffer 611 receives external data ext.DQ in synchronism with timing t5 of external data strobe signal ext.DQS from a corresponding terminal (one of terminals 150 to 15n) to buffer received data ext.DQ. Data input buffer 611 outputs buffered data to latch circuits 612 and 614 as data int.DQ.

Then, latch circuits 612 and 614 receives data int.DQ at a timing prior to timing t6 of internal data strobe signal int.DQS. The same operation as the description in FIG. 9 is performed by the following circuits: latch circuits 612, 613, 614; the transfer gate constituted of N-channel MOS transistor 615 and P-channel MOS transistor 616, the transfer gate constituted of N-channel MOS transistor 617 and P-channel MOS transistor 618, the transfer gate constituted of P-channel MOS transistor 619 and N-channel MOS transistor 620, and the transfer gate constituted of P-channel MOS transistor 621 and N-channel MOS transistor 622, and latch circuits 625 and 626, and latch circuits 625 and 626 output data D0 to respective latch circuits 632 and 635 in synchronism with timing t7 of internal data strobe signal int.DQS.

Latch circuits 632 and 635 latch data D0 in synchronism with the inverted signal of dummy clock DSCLK to output latched data D 1 to respective latch circuits 633 and 636 in synchronism with timing a half cycle prior to timing t8 of dummy clock DSCLK, and latch circuits 633 and 636 latch data D1 in synchronism with dummy clock DSCLK. Then, latch circuits 633 and 636 output data D2 to respective latch circuits 634 and 637 in synchronism with timing t8 of dummy clock DSCLK.

While latch circuits 634 and 637 begin reception of data D2 in synchronism with timing t8 of dummy clock DSCLK, latch circuits 634 and 637 are inactive during a period from timing t8 of dummy clock DSCLK till timing t9 of internal clock int.CLK to output no data. Latch circuits 634 and 637 are activated at timing t9 of internal clock int.CLK to output data D3.

Even in a case where, such a fashion, a phase difference arises between external data strobe signal ext.DQS and external clock ext.CLK and delays occur in internal data strobe signal int.DQS, dummy clock DSCLK and internal clock int.CLK, a smooth switch can be ensured between synchronizing signals for operation on data from internal data strobe signal int.DQS to internal clock int.CLK.

In the switch between synchronizing signals, dummy clock DSCLK exercises a function as a bridge over synchronizing signals for operation on data from internal data strobe signal int.DQS to internal clock int.CLK. Since dummy CLK generating circuit 52, as described above, has the same configuration as internal DQS generating circuit 53 and dummy clock DSCLK is generated on the basis of external clock ext.CLK, delay amount DT2 produced when dummy clock DSCLK is generated is the same as delay amount DT1 produced when internal data strobe signal int.DQS is generated. Therefore, a phase difference between dummy clock DSCLK and internal data strobe signal int.DQS is equal to a phase difference between external data strobe signal ext.DQS and external clock ext.CLK. Since hold time tDSH is determined such that a switch between synchronizing signals for operation on data from external data strobe signal ext.DQS to external clock ext.CLK is enabled, a switch between synchronizing signals for operation on data from internal data strobe signal int.DQS to dummy clock DSCLK can be infallibly realized when delay amount DT2 coincides with delay amount DT1.

Since dummy clock DSCLK and internal clock int.CLK are generated on the basis of external clock ext.CLK, a relation between a rising edge of dummy clock DSCLK and a rising edge of internal clock int.CLK is determined by a relation between delay amount DT2 and delay amount DT3.

Analysis being made of a case where delay amount DT3 changes over a range of from 0 to 180 degrees, a timing t9 of internal clock int.CLK in this case changes over a range of from timing t91 to timing t92. Since latch circuits 634 and 637 are activated when internal clock int.CLK is driven to H level and internal clock int.CLK switches from L level to H level at timing t9, latch circuits 634 and 637 can infallibly output data D2 received from respective latch circuits 633 and 636 as data D3.

Analysis being made of a case where no delay occurs in internal data strobe signal int.DQS and dummy clock DSCLK, but a delay occurs in internal clock int.CLK, since DT1=DT2=0 in this case, data D2 is outputted from latch circuits 633 and 636 to respective latch circuits 634 to 637 in synchronism with timing t91. Furthermore, in this case, even if delay amount DT3 changes over a range of from 0 to 180 degrees, that is if timing t9 changes over a range of from timing t91 to timing t92, latch circuits 634 and 637 can infallibly output data D2 as data D3 since the circuits have been activated at a timing at which data D2 is inputted.

As described above, not only is dummy clock DSCLK generated on the basis of external clock ext.CLK with the same circuit configuration as internal DQS generating circuit 53, but a smooth switch between synchronizing signals for operation on data from internal data strobe signal int.DQS to internal clock int.CLK can also be performed by providing serial/parallel conversion circuits 600 to 60n latching data sequentially in synchronism with internal data strobe signal int.DQS, dummy clock DSCLK and internal clock int.CLK.

Variations in delay amounts DT1, DT2 and DT3 produced when internal strobe signal int.DQS, dummy clock DSCLK and internal clock int.CLK are generated cause variations in set-up time tDSS and hold time tDSH. If, since internal data strobe signal int.DQS, dummy clock DSCLK and internal clock int.CLK have the same frequency as each other, a frequency of the signals is f [Hz], a variation of set-up time tDSS in semiconductor memory device 100 a [sec], a variation of set-up time tDSH in semiconductor memory device 100 b [sec], a tolerance of set-up time tDSS and hold time tDSH c by definition, given that f=100 M[Hz], c=0.2 tCLK, a=b=700 p [sec] in a currently used DDR-DRAM, c/f=0.2/(100×10⁶)=2×10⁻⁹ [sec], a+b=700+700=1400 p[sec]=1.4×10⁻⁹ [sec]. Therefore, a relation of c/f>a+b is satisfied.

The quotient c/f expresses a length of set-up time tDSS or hold time tDSH of internal data strobe signal int.DQS, dummy clock DSCLK or internal clock int.CLK and the sum a+b expresses the sum of variations of set-up time tDSS and hold time tDSH. Therefore, the relation of c/f>a+b expresses that frequency f is determined such that set-up time tDSS or hold time tDSH vary in a range shorter than the length of set-up time tDSS or hold time tDSH set in DDR-DRAM.

Therefore, in the present invention, a frequency f of internal data strobe signal int.DQS, dummy clock DSCLK or internal clock int.CLK is determined such that the relation of c/f>a+b is satisfied.

Referring again to FIG. 1, description will be given of operation for inputting/outputting data DQ to/from a memory cell in semiconductor memory device 100. First of all, a write operation for data DQ is taken up. When a write operation begins, control signals such as row address strobe signal /RAS are inputted to buffer 10 and buffer 10 buffers the control signals such as row address strobe signal /RAS to output the buffered signals to control circuit 40. Buffer 20 receives address A0 to Am (ADD) to buffer address A0 to Am and to output the address to control circuit 40 and input circuit 60. Buffer 30 receives clock enable signal CKE, clock CLK (external clock ext.CLK), data strobe signal DQS (UDQS or LDQS), select signal ULSEL and data strobe enable signal DQSEN to buffer clock enable signal CKE, clock CLK (external clock ext.CLK), data strobe signal DQS (UDQS or LDQS), select signal ULSEL and data strobe enable signal DQSEN. Buffer 30 outputs buffered clock enable signal CKE to control circuit 40 and synchronizing signal generating circuit 50, and outputs clock CLK (external clock ext.CLK), data strobe signal DQS (UDQS or LDQS), select signal ULSEL and data strobe enable signal DQSEN to synchronizing signal generating circuit 50.

Internal voltage generating circuit 140 generates internal power supply voltage int.VDD on the basis of external power supply voltage VDD supplied externally to supply generated internal power supply voltage int.VDD to synchronizing signal generating circuit 50. Note that external power supply voltage VDD is supplied directly to synchronizing signal generating circuit 50.

Then, synchronizing signal generating circuit 50, as described above, generates internal data strobe signal int.DQS, dummy clock DSCLK and internal clock int.CLK on the basis of clock enable signal CKE, clock CLK (external clock ext.CLK), data strobe signal DQS (UDQS or LDQS), select signal ULSEL, data strobe enable signal DQSEN, internal power supply voltage int.VDD and external power supply voltage VDD to output generated internal clock int.CLK to control circuit 40 and input circuit 60, and output internal data strobe signal int.DQS and dummy clock DSCLK to input circuit 60.

Control circuit 40 determines whether or not clock enable signal CKE is at H level at a rise of internal clock int.CLK and if at H level, internal clock int.CLK is regarded as effective. Control circuit 40 outputs address A0 to Am inputted from buffer 20 at the timing at which row address strobe signal /RAS switches from H level to L level to row decoder 90 as the row address in synchronism with internal clock int.CLK. Control circuit 40 outputs address A0 to Am inputted from buffer 20 at the timing at which column address strobe signal /CAS switches from H level to L level to column decoder 70 as the column address in synchronism with internal clock int.CLK. Furthermore, control circuit 40 outputs write enable signal /WE to input circuit 60 in synchronism with internal clock int.CLK and outputs output enable signal /OE to output circuit 130 in synchronism with internal clock int.CLK.

Then, input circuit 60 is activated in response to write enable signal /WE at L level from control circuit 40 and, as described above, not only converts inputted data DQ0 to DQn from serial to parallel, but also switches between synchronizing signals for operation on converted data DQO to DQn from internal data strobe signal int.DQS to internal clock int.CLK through dummy clock DSCLK to output data in synchronism with internal clock int.CLK to input/output lines I/O as write data.

On the other hand, column decoder 70 decodes the column address from control circuit 40 to activate bit line pair BLk and /BLk designated by the decoded column address. Row decoder 90 decodes the row address inputted from control circuit 40 to activate word line Wj designated by the decoded row address. Sense amplifier 80 writes write data inputted through input/output lines I/O to activated bit line pair BLk and /BLk. In such a way, the write data is written to the memory cell designated by activated bit line pair Blk and /Blk and word line Wj.

Next, description will be given of a read operation for data from the memory cell. The operation from the time when control circuit 40 outputs the column address and the row address to column decoder 70 and row decoder 90, respectively, till the time when the circuit outputs write enable signal /WE and output enable signal /OE to input circuit 60 and output circuit 130, respectively, is the same as in data writing. In this case, control circuit 40 outputs output enable signal /OE at L level to output circuit 130 and write enable signal /WE at H level to input circuit 60. With such an operation performed, output circuit 130 is activated, while input circuit 60 is deactivated.

Then, column decoder 70 decodes the column address from control circuit 40 to activate bit line pair BLk and /BLk designated by the decoded column address. Row decoder 90 decodes the row address from control circuit 40 to activate word line Wj designated by the decoded row address. Then, data is read out from a memory cell designated by activated bit line pair BLk and /BLk and word line Wj and sense amplifier 80 receives the read data through activated bit line pair BLk and /BLk. Sense amplifier 80 amplifies the read data to output the amplified read data to output circuit 130 through input/output lines I/O.

On the other hand, DQS generating circuit 120 generates data strobe signal DQSR to output generated data strobe signal DQSR onto output circuit 130. Output circuit 130 outputs read data inputted from sense amplifier 80 through input/output lines I/O to input/output terminals 150 to 15n in synchronism with data strobe signal DQSR from DQS generating circuit 120. With such an operation applied, a read operation for data ends.

Note that in the above operation, control circuit 40, column decoder 70, sense amplifier 80 and row decoder 90 constitutes peripheral circuitry inputting/outputting data to/from each of plural memory cells included in memory cell array 110.

In the present invention, DDR-DRAM, SRAM, a flash memory and others are considered as semiconductor memory device 100.

According to the first embodiment, since a semiconductor memory device includes: a synchronizing signal generating circuit that generates the internal data strobe signal on the basis of the external data strobe signal, generates the dummy clock on the basis of the external clock with the same circuit configuration as the internal DQS generating circuit that generates internal data strobe signal and generates the internal clock on the basis of the external clock; and the input circuit not only converting data from serial to parallel but also latching the converted data sequentially in synchronism with the internal data strobe signal, the dummy clock and the internal clock to output data to internal circuits, a smooth switch can be realized between synchronizing signals for operation on data from the internal data strobe signal to the internal clock, even if the external data strobe signal and the external clock shift in phase therebetween.

Second Embodiment

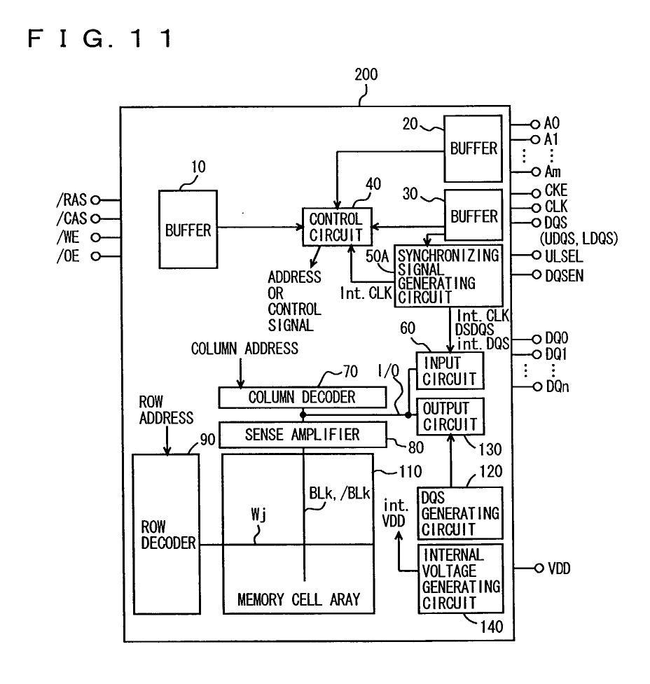

Referring to FIG. 11, a semiconductor memory device 200 according to the second embodiment is the same as semiconductor memory device 100 in configuration except for replacement of synchronizing signal generating circuit 50 of semiconductor memory device 100 with a synchronizing signal generating circuit 50A.

Synchronizing signal generating circuit 50A generates a dummy data strobe signal DSDQS instead of dummy clock DSCLK in semiconductor memory device 100 to output generated dummy data strobe signal DSDQS to input circuit 60.

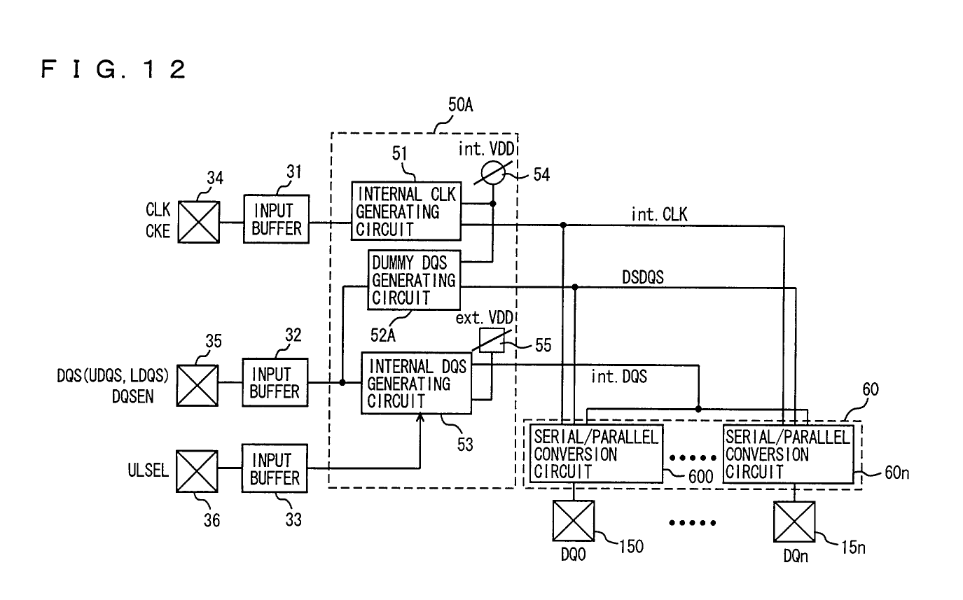

Referring to FIG. 12, synchronizing signal generating circuit 50A is obtained by replacing dummy CLK generating circuit 52 of synchronizing signal generating circuit 50 with dummy DQS generating circuit 52A, and the other constituents are the same as corresponding constituents of the configuration of synchronizing signal generating circuit 50.

Dummy DQS generating circuits 52A is of the same circuit configuration as that of internal CLK generating circuit 51 and generates dummy data strobe signal DSDQS on the basis of data strobe signal DQS. Dummy DQS generating circuit 52A outputs generated dummy data strobe signal DSDQS to input circuit 60. Then, each of serial/parallel conversion circuit 600 to 60n of input circuit 60 makes a switch between synchronizing signals for operation on data from internal data strobe signal int.DQS to internal clock int.CLK through dummy data strobe signal DSDQS instead of dummy clock DSCLK in the first embodiment.

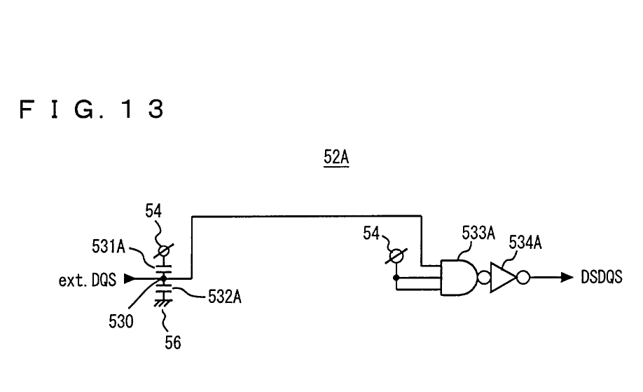

Referring to FIG. 13, dummy DQS generating circuit 52A includes: capacitor 531A and 532A; a NAND gate 533A; and an inverter 534A. Capacitor 531A is connected between power supply node 54 and a node 530 and capacitor 532A is connected between node 530 and ground node 56. Capacitors 531A and 532A exercise the same functions as those of respective capacitors 511 and 512 of internal CLK generating circuit 51 described above (see FIG. 3).

NAND gate 533A receives external data strobe signal ext.DQS whose rising and falling slopes are rendered gentler by capacitors 531A and 532A and a signal at H level of internal power supply voltage int.VDD from power supply node 54 to perform a logical product operation on these signals. Then, NAND gate 533A inverts a result of the operation to output the inverted result to inverter 534A. Inverter 534A inverts an output signal of NAND gate 533A to output dummy data strobe signal DSDQS.

Since NAND gate 533A is a 3-input NAND gate and receives a signal at H level of internal power supply voltage int.VDD from power supply node 54 at two input terminals thereof and external data strobe signal ext.DQS at the residual one input terminal, NAND gate 533A infallibly outputs a signal obtained by inverting a logical level of external data strobe signal ext.DQS to inverter 534A. Since capacitors 531A and 532A, and NAND gate 533A and inverter 534A correspond to capacitors 511 and 512, NAND gate 518 and inverter 519 of internal CLK generating circuit 51, dummy DQS generating circuit 52A has the same circuit configuration as internal CLK generating circuit 51. Dummy DQS generating circuit 52A is supplied with internal power supply voltage int.VDD from power supply node 54 in a similar manner to the case of internal CLK generating circuit 51 (see FIG. 3).

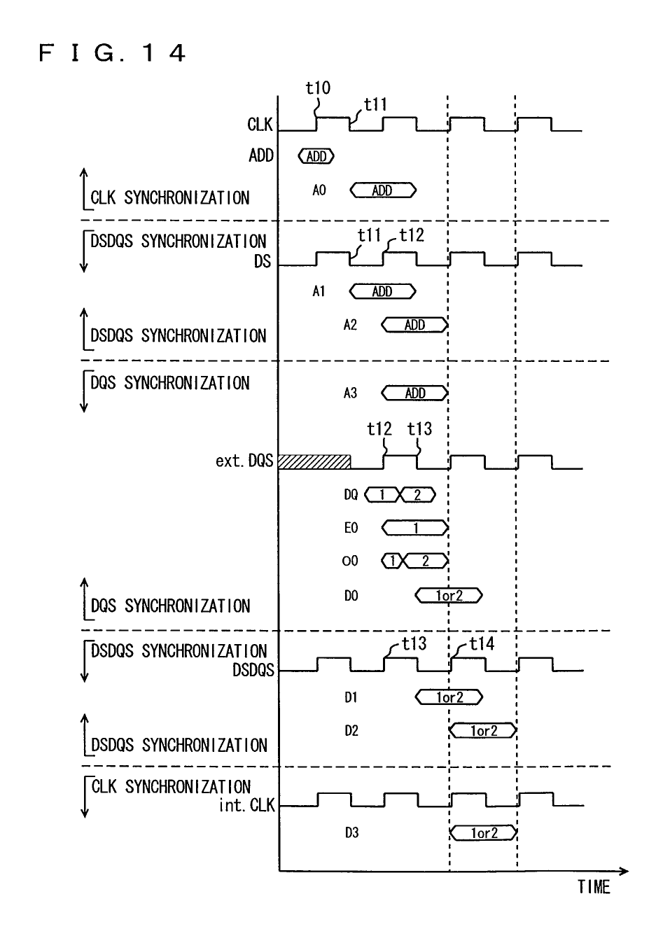

Referring to FIGS. 6 and 14, description will be given of operation in each of serial/parallel conversion circuits 600 to 60n in a case where dummy data strobe signal DSDQS instead of dummy clock DSCLK. Latch circuit 627, when receiving address ADD from buffer 20 in synchronism with timing t10, latches address ADD in synchronism with the inverted signal of internal clock int.CLK to output latched address to latch circuit 628. Latch circuit 628 latches address latched by latch circuit 627, in synchronism with internal clock int.CLK and latch circuit 629 latches address latched by latch circuit 628, in synchronism with the inverted signal of internal clock int.CLK to output latched address A0 to latch circuit 630 in synchronism with timing t11.

Latch circuit 630 latches address A0 in synchronism with the inverted signal of dummy data strobe signal DSDQS from dummy DQS generating circuit 52A. In this case, since timing t11 at which address A0 is outputted from latch circuit 629 is a timing at which dummy data strobe signal DSDQS falls from H level to L level, latch circuit 630 outputs address A0 received from latch circuit 629 as address A1 at timing t11 to latch circuit 631.

Latch circuit 631 latches address A1 in synchronism with dummy data strobe signal DSDQS to output latched address A2 to latch circuit 624 in synchronism with timing t12 at which dummy data strobe signal DSDQS switches from L level to H level.

Then, latch circuit 624 latches address A2 in synchronism with internal data strobe signal int.DQS to output latched address A3 to the gate terminals of N-channel MOS transistors 615 and 622, P-channel MSO transistors 618 and 619 and inverter 623. In this case, since internal data strobe signal int.DQS (indicated as [ext.DQS] in FIG. 14) switches from L level to H level at timing t12 at which latch circuit 631 outputs address A2, latch circuit 624 is activated at timing t12 to output address A2 as address A3 in synchronism with timing t12.

On the other hand, data input buffer 611 receives data DQ (one of data DQ0 to DQn) from the corresponding terminal (one of terminals 150 to 15n) in synchronism with external data strobe signal ext.DQS to buffer received data DQ. Data input buffer 611 outputs buffered data DQ to latch circuits 612 and 614. Then, since latch circuit 612 receives data DQ at a timing prior to timing t12 for the first time, the circuit outputs received data DQ to latch circuit 613 during a period from a timing at which latch circuit 612 receives data DQ for the first time till timing t12. While latch circuit 612 receives internal data strobe signal int.DQS having switched from H level to L level at timing t12 to be deactivated, latch circuit 612 maintains the previous outputting state prior to the deactivation; therefore latch circuit 612 continues to output data DQ to latch circuit 613. Thereby, since latch circuit 613 is activated at timing t12, latch circuit 613 outputs data DQ received from latch circuit 612, in synchronism with timing t12 as data E0 to the source terminals of N-channel MOS transistor 615 and P-channel MOS transistor 616, and the source terminals of N-channel MOS transistor 617 and P-channel MOS transistor 618. In this case, data E0 is constituted of only data 1 of data 1 and 2 constituting data DQ.

On the other hand, since latch circuit 614 latches data DQ in synchronism with internal data strobe signal int.DQS, the circuit is inactive at a timing at which the circuit receives data DQ from data input buffer 611 for the first time and outputs no data. Latch circuit 614 is activated at timing t12 and thereafter, outputs data DQ as data O0 to the source terminals of P-channel MOS transistor 619 and N-channel MOS transistor 620, and the source terminals of P-channel MOS transistor 621 and N-channel MOS transistor 622. In this case, since latch circuit 614, when being activated at timing t12, outputs data DQ as is, data O0 is constituted of part of data 1 and part of data 2 inputted to latch circuit 614 at timing t12 and thereafter.

Since the transfer gate constituted of N-channel MOS transistor 615 and P-channel MOS transistor 616 and the transfer gate constituted of N-channel MOS transistor 617 and P-channel MOS transistor 618 are complementarily turned on/off by addresses A3 and /A3, data E0 is inputted to latch circuit 625 or 626. Since the transfer gate constituted of P-channel MOS transistor 619 and N-channel MOS transistor 620 and the transfer gate constituted of P-channel MOS transistor 621 and N-channel MOS transistor 622 are complementarily turned on/off by addresses A3 and /A3, data O0 is inputted to latch circuit 625 or 626. Therefore, latch circuits 625 and 626 outputs data D0 constituted of data 1 or 2 to respective latch circuits 632 and 635. In this case, since latch circuits 625 and 626 latch data E0 (or O0) in synchronism with the inverted signal of internal data strobe signal int.DQS, the circuits are inactive at timing t12 at which the circuits receive data E0 (O0) for the first time and, after activation at timing t13, output data D0 in synchronism with timing t13.

Since latch circuits 632 and 635 latch data in synchronism with the inverted signal of dummy data strobe signal DSDQS, the circuits are active at timing t13 at which the circuits receives data D0 for the first time and output data D0 received from respective latch circuits 625 and 626 as data D1 being the same as data D0. Since latch circuits 633 and 636 latch data in synchronism with dummy data strobe signal DSDQS, the circuits are inactive at timing t13 at which the circuits receive data D1 for the first time and latch data D1 till timing t14 at which the circuits are activated to output latched data D2 to respective latch circuits 634 and 637 in synchronism with timing t14. Then, since latch circuits 634 and 637 latch data in synchronism with internal clock int.CLK, the circuits are active at timing t14 at which the circuits receive data D2 for the first time and outputs data D2 received from respective latch circuits 633 and 636, as data D3 in synchronism with timing t14.

In such a fashion, each of serial/parallel conversion circuits 600 to 60n not only converts data DQ from serial to parallel in synchronism with internal data strobe signal int.DQS, but also latches data DQ sequentially in synchronism with internal data strobe signal int.DQS, dummy data strobe signal DSDQS, and internal clock int.CLK to thereby performing a switch between synchronizing signals for operation on data DQ inputted in synchronism with external data strobe signal ext.DQS from internal data strobe signal int.DQS to internal clock int.CLK for use in inputting/outputting to/from the memory cell through dummy data strobe signal DSDQS.

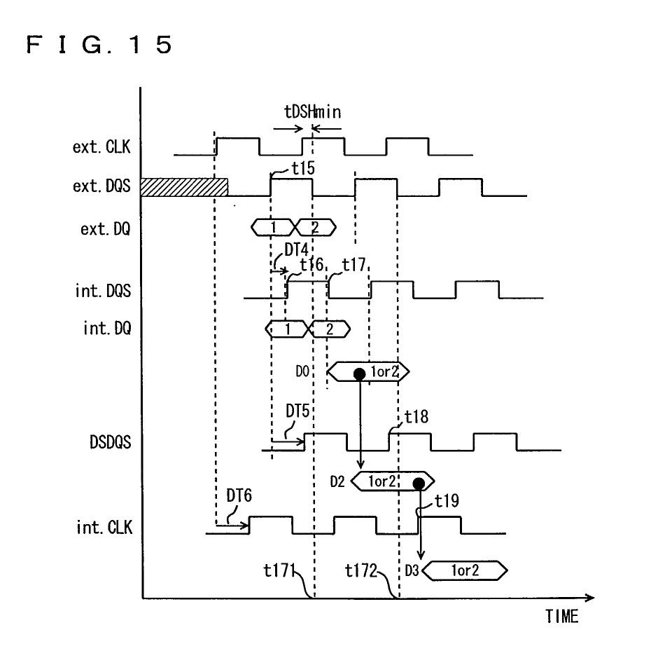

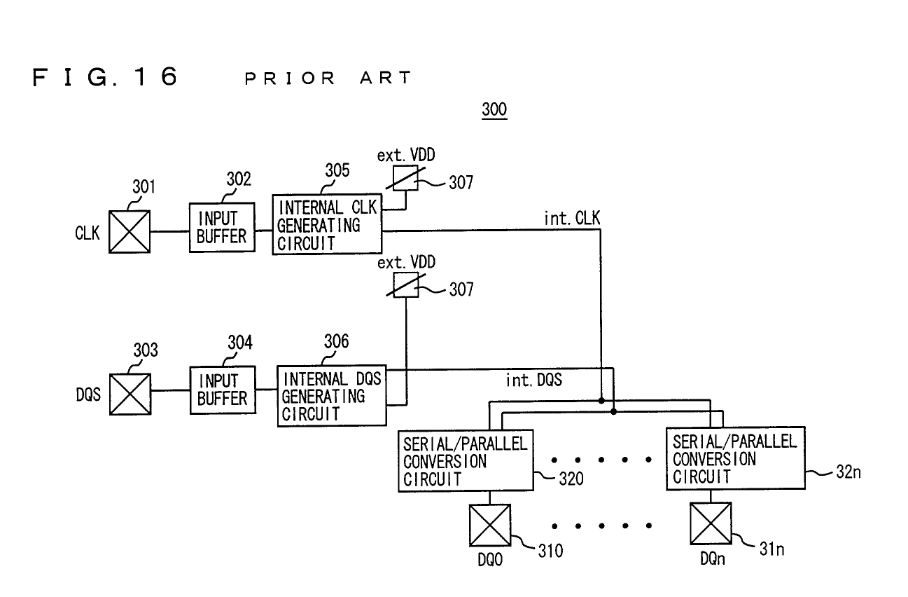

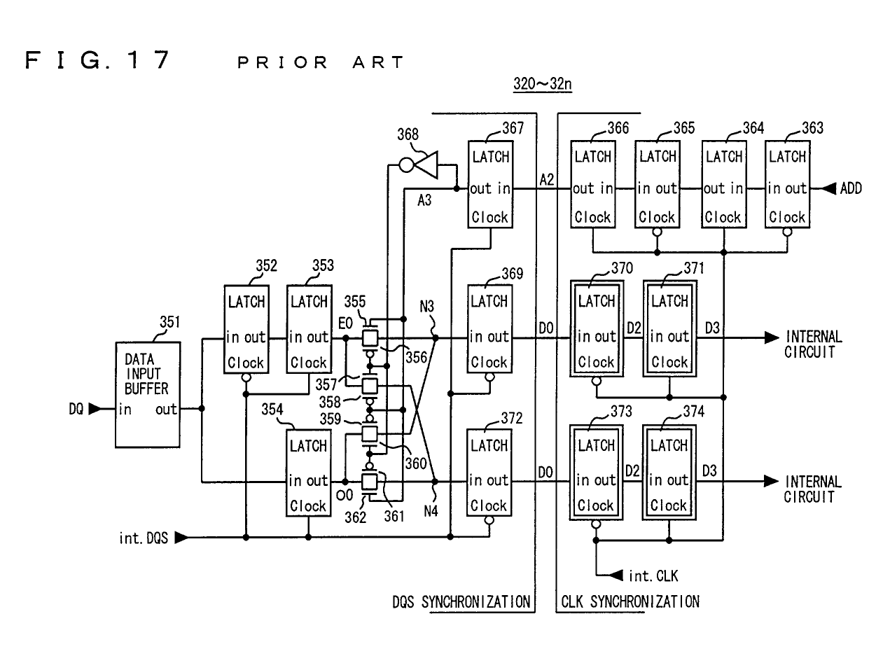

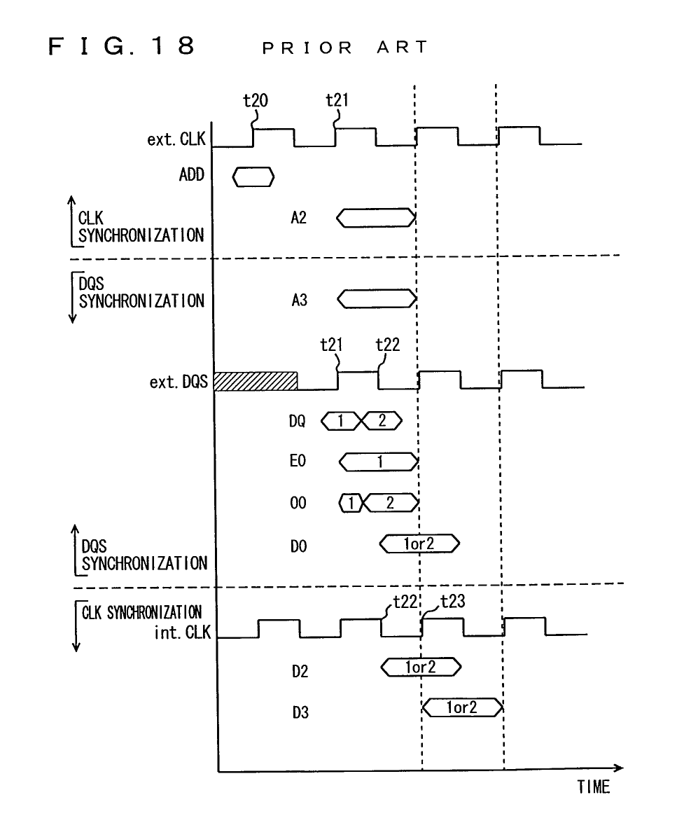

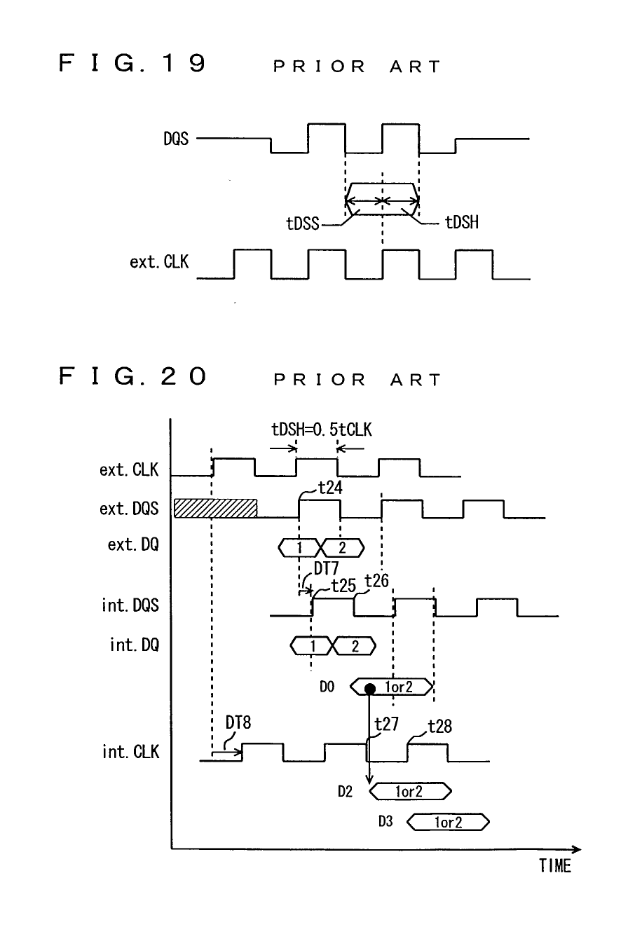

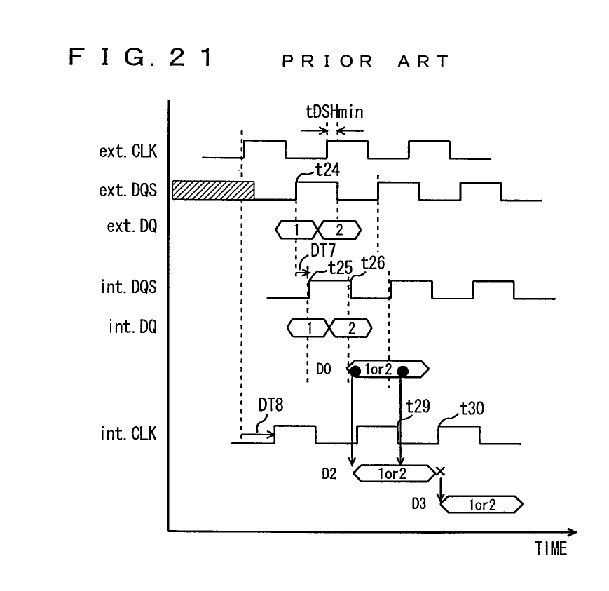

FIG. 14 shows a case where external data strobe signal ext.DQS and external clock ext.CLK coincide with each other in phase, internal data strobe signal int.DQS and dummy data strobe signal DSDQS does not lag behind external data strobe signal ext.DQS and internal clock int.CLK does not lag behind external clock ext.CLK. In reality, however, external data strobe signal ext.CLK does not coincide with external clock ext.CLK in phase, internal data strobe signal int.DQS and dummy data strobe signal DSDQS lags behind external data strobe signal ext.DQS and internal clock int.CLK lags behind external clock ext.CLK. Therefore, FIG. 15 shows a case where a phase difference arises between external data strobe signal ext.DQS and external clock ext.CLK, and delays occur in internal data strobe signal int.DQS, dummy data strobe signal DSDQS and internal clock int.CLK. In FIG. 15, hold time tDSH showing a phase difference between external data strobe signal ext.DQS and external clock ext.CLK is the minimum value tDSHmin, a delay amount of internal data strobe signal int.DQS relative to external data strobe signal ext.DQS is DT4, a delay amount of dummy data strobe signal DSDQS relative to external data strobe signal ext.DQS is DT5 and a delay amount of internal clock int.CLK relative to external clock ext.CLK is DT6.

Referring to FIG. 15, the above description is given of operation from the time when address ADD is inputted from buffer 20 to latch circuit 627 till the time when latch circuit 624 outputs address A3. On the other hand, data input buffer 611 receives data ext.DQ from the corresponding terminal (one of terminals 150 to 15n) in synchronism with timing t15 of external data strobe signal ext.DQS to buffer received data ext.DQ. Data input buffer 611 outputs buffered data as data int.DQ to latch circuits 612 and 614.

Then, latch circuits 612 and 614 receives data int.DQ at a timing prior to timing t16 of internal data strobe signal int.DQS. The same operation as the description in FIG. 14 is performed in the following circuits: latch circuits 612, 613 and 614; the transfer gate constituted of N-channel MOS transistor 615 and P-channel MOS transistor 616, the transfer gate constituted of N-channel MOS transistor 617 and P-channel MOS transistor 618, the transfer gate constituted of P-channel MOS transistor 619 and N-channel MOS transistor 620 and the transfer gate constituted of P-channel MOS transistor 621 and N-channel MOS transistor 622; and latch circuits 625 and 626, and latch circuits 625 and 626 outputs data D0 to respective latch circuits 632 and 635 in synchronism with timing t17 of internal data strobe signal int.DQS.

Then, latch circuits 632 and 635 latch data D0 in synchronism with the inverted signal of dummy data strobe signal DSDQS to output latched data D1 in synchronism with timing a half cycle prior to timing t18 of dummy data strobe signal DSDQS to respective latch circuits 633 and 636 and latch circuits 633 and 636 latch data D 1 in synchronism with dummy data strobe signal DSDQS. Then, latch circuits 633 and 636 output data D2 in synchronism with timing t18 of dummy data strobe signal DSDQS to respective latch circuits 634 and 637.

While latch circuits 634 and 637 begins reception of data D2 in synchronism with timing t18 of dummy data strobe signal DSDQS, latch circuits 634 and 637 is inactive during a period from timing t18 of dummy data strobe signal DSDQS till timing t19 of internal clock int.CLK to output no data. Latch circuits 634 and 637 are activated at timing t19 of internal clock int.CLK to output data D3.

Even in a case where, in such a fashion, a phase difference arises between external data strobe signal ext.DQS and external clock ext.CLK and delays occur in internal data strobe signal int.DQS, dummy data strobe signal DSDQS and internal clock int.CLK, a smooth switch can be ensured between synchronizing signals for operation on data from internal data strobe signal int.DQS to internal clock int.CLK through dummy data strobe signal DSDQS.

In the switch between synchronizing signals, dummy data strobe signal DSDQS exercises a function as a bridge over synchronizing signals for operation on data from internal data strobe signal int.DQS to internal clock int.CLK. Since, as described above, dummy DQS generating circuit 52A has the same configuration as that of internal clock generating circuit 51 and dummy data strobe signal DSDQS is generated on the basis of external data strobe signal ext.DQS, a delay amount DT5 produced when dummy data strobe signal DSDQS is generated is the same as a delay amount DT6 produced when internal clock int.CLK is generated. Therefore, a phase difference between dummy data strobe signal DSDQS and internal clock signal int.CLK is the same as that between external data strobe signal ext.DQS and external clock ext.CLK. Since internal data strobe signal int.DQS and dummy data strobe signal DSDQS are generated on the basis of external data strobe signal ext.DQS, a relation between a rising edge of internal data strobe signal int.DQS and a rising edge of dummy data strobe signal DSDQS is determined by a relation between delay amounts DT4 and DT5.

Analysis being made of a case where delay amount DT4 changes over a range of from 0 to 180 degrees, timing t17 of internal data strobe signal int.DQS in this case changes over a range of from timing t171 to timing t172. Therefore, a timing at which data D0 is outputted for the first time changes over a range of from timing t171 to timing t172. Latch circuits 632 and 635 is activated when dummy data strobe signal DSDQS assumes L level and latch circuits 633 and 636 are activated when dummy data strobe signal DSDQS changes from L level to H level, while since dummy data strobe signal DSDQS infallibly switches from H level to L level during a period when data D0 is outputted even if a timing at which data D0 is outputted for the first time changes over a range of from timing t171 to timing t172, latch circuits 632 and 635 can infallibly capture data D0 and latch circuits 633 and 636 can infallibly latch data D1 to output data D2 to respective latch circuits 634 and 637.

In a case where no delay occurs in dummy data strobe signal DQDQS and internal clock int.CLK and a delay occurs in internal data strobe signal int.DQS as well, as described above, latch circuits 632 and 635 can infallibly capture data D0 and latch circuits 633 and 636 can infallibly latch data D1 to output data D2 to respective latch circuits 634 and 637.

Therefore, a switch can be made between synchronizing signals for operation on data from internal data strobe signal int.DQS to dummy data strobe signal DSDQS.

Since hold time tDSH is set such that a switch can be made between synchronizing signals for operation on data from external data strobe signal ext.DQS to external clock ext.CLK, a switch can be infallibly made between synchronizing signals for operation on data from dummy data strobe signal DSDQS to internal clock int.CLK if delay amount DT5 coincides with delay amount DT6.

As described above, by not only generating dummy data strobe signal DSDQS on the basis of external data strobe signal ext.DQS with the same circuit configuration as that of internal CLK generating circuit 51, but also providing serial/parallel conversion circuits 600 to 60n latching data sequentially in synchronism with internal data strobe signal int.DQS, dummy data strobe signal DSDQS and internal clock int.CLK, a smooth switch can be realized between synchronizing signals for operation on data from internal data strobe signal int.DQS to internal clock int.CLK.

Operation in inputting/outputting data to/from a memory cell in semiconductor memory device 200 is the same as the operation in the description in the first embodiment only with replacement of dummy clock DSCLK by dummy data strobe signal DSDQS.

The other constituents and workings of the construction are the same as those of the construction of the first embodiment.

According to the second embodiment, since a semiconductor memory device includes: the synchronizing signal generating circuit that generates the internal clock on the basis of the external clock, generates the dummy data strobe signal on the basis of external data strobe signal with the same circuit configuration as the internal CLK generating circuit generating the internal clock and generates the internal data strobe signal on the basis of the external data strobe signal; and the input circuit not only converts data from serial to parallel, but also outputs the converted data to internal circuits sequentially in synchronism with the internal data strobe signal, the dummy data strobe signal and the internal clock, the smooth switch can be ensured between synchronizing signals for operation on data from the internal data strobe signal to the internal clock, even if the external data strobe signal and the external clock shift in phase therebetween.

Note that while in the above description, data strobe enable signal DQSEN and select signal ULSEL are inputted from outside semiconductor memory devices 100 or 200, data strobe enable signal DQSEN and select signal ULSEL in the present invention, may be generated in semiconductor memory devices 100 or 200.

In a case where data strobe enable signal DQSEN and select signal ULSEL is generated in semiconductor memory device 100 or 200, when receiving write enable signal /WE, which is a write command, from buffer 10, control circuit 40 generates data strobe enable signal DQSEN to output generated data strobe enable signal DQSEN to internal DQS generating circuit 53 of synchronizing signal generating circuits 50 or 50A. Select signal ULSEL is selectively given to internal DQS generating circuit 53 from a pad supplying a voltage of a signal at H level or a pad supplying a voltage of a signal at L level. Select signal ULSEL at H level or L level is supplied from respective pads to internal DQS generating circuit 53 according to a word configuration (×16, ×8 or ×4) of semiconductor memory device 100 or 200.

Although the present invention has been described and illustrated in detail, it is clearly understood that the same is by way of illustration and example only and is not to be taken by way of limitation, the spirit and scope of the present invention being limited only by the terms of the appended claims.

What is claimed is:

1. A semiconductor memory device inputting/outputting data to/from memory cells in synchronism with a rise and a fall of a synchronizing signal, comprising:
a plurality of memory cells;
a synchronizing signal generating circuit receiving first and second synchronizing signals, generating a first internal synchronizing signal on the basis of said first synchronizing signal, generating a second internal synchronizing signal on the basis of said second synchronizing signal, and generating a third internal synchronizing signal by means of the same circuit configuration as a circuit generating one of said first and second internal synchronizing signals on the basis of one of said first and second synchronizing signal;
a peripheral circuit inputting/outputting data to/from each of said plurality of memory cells in synchronism with said rise and said fall of said second internal synchronizing signal; and
an input circuit receiving data inputted externally in synchronism with said first synchronizing signal, latching the received data sequentially in synchronism with said first internal synchronizing signal, said third internal synchronizing signal and said second internal synchronizing signal to output the latched data to said peripheral circuit.

2. The semiconductor memory device according to claim 1, wherein
said synchronizing signal generating circuit generates said third internal synchronizing signal on the basis of said second synchronizing signal by means of the same configuration as a circuit generating said first internal synchronizing signal.

3. The semiconductor memory device according to claim 2, wherein
said synchronizing signal generating circuit includes:
a first signal generating circuit generating said first internal synchronizing signal on the basis of said first synchronizing signal;
a second signal generating circuit generating said second internal synchronizing signal on the basis of said second synchronizing signal; and
a third signal generating circuit having the same circuit configuration as that of said first signal generating circuit, and generating said third internal synchronizing signal on the basis of said second synchronizing signal.

4. The semiconductor memory device according to claim 3, wherein
said first and third signal generating circuits include an even number of signal inverting elements connected in series, each of which inverts an input signal to output an output signal.

5. The semiconductor memory device according to claim 2, wherein
said input circuit includes:
a first latch circuit latching said data in synchronism with said first internal synchronizing signal;
a second latch circuit latching data outputted from said first latch circuit in synchronism with said third internal synchronizing signal; and
a third latch circuit latching data outputted from said second latch circuit in synchronism with said second internal synchronizing signal to output the latched data to said peripheral circuit.

6. The semiconductor memory device according to claim 1, wherein
said synchronizing signal generating circuit generates said third internal synchronizing signal on the basis of said first synchronizing signal by means of the same circuit configuration as a circuit generating said second internal synchronizing signal.

7. The semiconductor memory device according to claim 6, wherein
said synchronizing signal generating circuit includes:
a first signal generating circuit generating said first internal synchronizing signal on the basis of said first synchronizing signal;
a second signal generating circuit generating said second internal synchronizing signal on the basis of said second synchronizing signal; and
a third signal generating circuit having the same circuit configuration as that of said second signal generating circuit, and generating said third internal synchronizing signal on the basis of said first synchronizing signal.

8. The semiconductor memory device according to claim 7, wherein
said second and third signal generating circuits include:
a first logical element inverting an input signal in response to a logical level of said input signal to output an output signal; and
a second logical element inverting the output signal from said first logical element.

9. The semiconductor memory device according to claim 6, wherein
said input circuit includes:
a first latch circuit latching said data in synchronism with said first internal synchronizing signal;
a second latch circuit latching data outputted from said first latch circuit in synchronism with said third internal synchronizing signal; and
a third latch circuit latching data outputted from said second latch circuit in synchronism with said second internal synchronizing signal to output the latched data to said peripheral circuit.

10. The semiconductor memory device according to claim 1, wherein
in cases where: a time till a first falling edge of said first internal synchronizing signal adjacent to a rising edge of said second internal synchronizing signal from said rising edge of said second internal synchronizing signal is a set-up time; a time till a second falling edge adjacent to said rising edge which is different from said first falling edge of said internal synchronizing signal from said rising edge is a hold time; a variation of said set-up time in the semiconductor memory device is “a”; a variation of said hold time in the semiconductor memory device is “b”; a tolerance of said set-up time and said hold time is “c”; and a frequency of said first, second and third internal synchronizing signals is ‘T’ by definition, a relation of c/f>a+b is satisfied.
